(19) United States
(12) Patent Application Publication
(10) Pub. No.: US 2024/0105805 A1
(43) Pub. Date: Mar. 28, 2024

(54) SEMICONDUCTOR STRUCTURE WITH DIELECTRIC WALL STRUCTURE AND METHOD FOR MANUFACTURING THE SAME

(71) Applicant: Taiwan Semiconductor Manufacturing Company, Ltd., Hsinchu (TW)

(72) Inventors: Chun-Sheng LIANG, PuyanTownship (TW); Hong-Chih CHEN, Changhua County (TW); Ta-Chun LIN, Hsinchu (TW); Shih-Hsun CHANG, Hsinchu (TW); Chih-Hao CHANG, Hsin-chu (TW)

(21) Appl. No.: 18/163,407

(22) Filed: Feb. 2, 2023

Related U.S. Application Data
(60) Provisional application No. 63/377,208, filed on Sep. 27, 2022.

(51) Int. Cl. H01L 29/423; H01L 21/8234; H01L 29/06; H01L 29/08; H01L 29/786

(52) U.S. Cl. CPC H01L 29/42392; H01L 21/823412; H01L 21/823418; H01L 21/823431; H01L 21/823481; H01L 29/0673; H01L 29/0847; H01L 29/78696

(57) ABSTRACT

Semiconductor structures and methods for manufacturing the same are provided. The semiconductor structure includes channel structures vertically stacked over a substrate and a source/drain structure laterally attached to the channel structures in the first direction. The semiconductor structure also includes a dielectric wall structure laterally attached to the channel structures in the second direction. The second direction is different from the first direction. In addition, the dielectric wall structure includes a bottom portion and a cap layer formed over the bottom portion. The semiconductor structure also includes an isolation feature vertically overlapping the cap layer of the dielectric wall structure and a gate structure formed around the channel structures and covering a sidewall of the isolation feature.

### PRIORITY CLAIM AND CROSS-REFERENCE

This application claims priority to U.S. Provisional Application Ser. No. 63/377,208, filed on Sep. 27, 2022, the entirety of which is incorporated by reference herein.

### BACKGROUND

The electronics industry is experiencing ever-increasing demand for smaller and faster electronic devices that are able to perform a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). However, integration of fabrication of the multi-gate devices can be challenging.

### BRIEF DESCRIPTION OF THE DRAWINGS

Aspects of the present disclosure are best understood from the following detailed description when read with the accompanying Figures. It should be noted that, in accordance with the standard practice in the industry, various features are not drawn to scale. In fact, the dimensions of the various features may be arbitrarily increased or reduced for clarity of discussion.

FIGS. 1A to 1C illustrate diagrammatic perspective views of intermediate stages of manufacturing a semiconductor structure in accordance with some embodiments.

FIGS. 2A to 2O, 2A-1 to 2O-1, and 2A-2 to 2O-2 illustrate the cross-sectional views of intermediate stages of manufacturing the semiconductor structure shown along line A-A′, B-B′, and C-C′ in FIG. 1C, respectively, in accordance with some embodiments.

FIG. 2E-3 illustrates an enlarged cross-sectional view of the semiconductor structure shown in the block BK of FIG. 2E in accordance with some embodiments.

FIGS. 2O-3 illustrates an enlarged cross-sectional view of the semiconductor structure in the block BK-O shown in FIG. 2O-1 in accordance with some embodiments.

FIG. 3 illustrates a cross-sectional view of a semiconductor structure in accordance with some embodiments.

FIG. 4A illustrates an enlarged cross-sectional view of a semiconductor structure in accordance with some embodiments.

FIG. 4B illustrates an enlarged cross-sectional view of a semiconductor structure in accordance with some embodiments.

FIGS. 5A and 5B illustrate enlarged cross-sectional views of intermediate stages of manufacturing a semiconductor structure in accordance with some embodiments.

FIGS. 6A and 6B illustrate enlarged cross-sectional views of intermediate stages of manufacturing a semiconductor structure in accordance with some embodiments.

FIGS. 7A and 7B illustrate cross-sectional views of a semiconductor structure in accordance with some embodiments.

FIG. 8 illustrates a cross-sectional view of a semiconductor structure in accordance with some embodiments.

FIGS. 9A to 9C illustrate cross-sectional views of intermediate stages of manufacturing a semiconductor structure in accordance with some embodiments.

FIG. 9C-1 illustrates a cross-sectional view of the semiconductor structure in the channel region in accordance with some embodiments.

FIG. 10 illustrates a cross-sectional view of a semiconductor structure in accordance with some embodiments.

FIGS. 11A to 11E illustrate cross-sectional views of intermediate stages of manufacturing a semiconductor structure in accordance with some embodiments.

FIG. 11D-1 illustrates a cross-sectional view of the intermediate stage of the semiconductor structure in the channel region in accordance with some embodiments.

FIG. 11E-1 illustrates a cross-sectional view of the semiconductor structure in the channel region in accordance with some embodiments.

FIG. 12 illustrates a cross-sectional view of a semiconductor structure in accordance with some embodiments.

FIGS. 13A to 13C illustrate cross-sectional views of intermediate stages of manufacturing a semiconductor structure in accordance with some embodiments.

FIG. 13C-1 illustrates a cross-sectional view of the semiconductor structure in the channel region in accordance with some embodiments.

FIG. 14 illustrates a cross-sectional view of a semiconductor structure in accordance with some embodiments.

FIGS. 15A to 15E illustrate cross-sectional views of intermediate stages of manufacturing a semiconductor structure in accordance with some embodiments.

FIG. 15E-1 illustrates a cross-sectional view of the semiconductor structure in the channel region in accordance with some embodiments.

FIGS. 16A to 16D illustrate cross-sectional views of intermediate stages of manufacturing a semiconductor structure in accordance with some embodiments.

FIG. 16D-1 illustrates a cross-sectional view of the semiconductor structure in the channel region in accordance with some embodiments.

FIG. 17 illustrates a cross-sectional view of a semiconductor structure in accordance with some embodiments.

FIG. 18 illustrates a diagrammatic top view of a semiconductor structure in accordance with some embodiments.

FIG. 19 illustrates one of the possible examples of the cross-sectional view of the semiconductor structure shown along line D-D′ of FIG. 18 in accordance with some embodiments.

FIG. 20 illustrates a diagrammatic top view of a semiconductor structure in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The nanostructure transistors (e.g. nanosheet transistors, nanowire transistors, multi-bridge channel transistors, nano-ribbon FET, and gate all around (GAA) transistors) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructures.

Embodiments of semiconductor structures and methods for forming the same are provided. The semiconductor structures may include channel structures, such as nanostructures, formed over a substrate and a gate structure formed around the channel structures. A dielectric wall structure, which includes a bottom portion and a cap layer, may be interposed between the gate structures and between the neighboring source/drain structures. The dielectric wall structure may prevent the bridging of the neighboring source/drain structures and may help the isolation of gate structures, and therefore the performance of the resulting semiconductor structure may be improved.

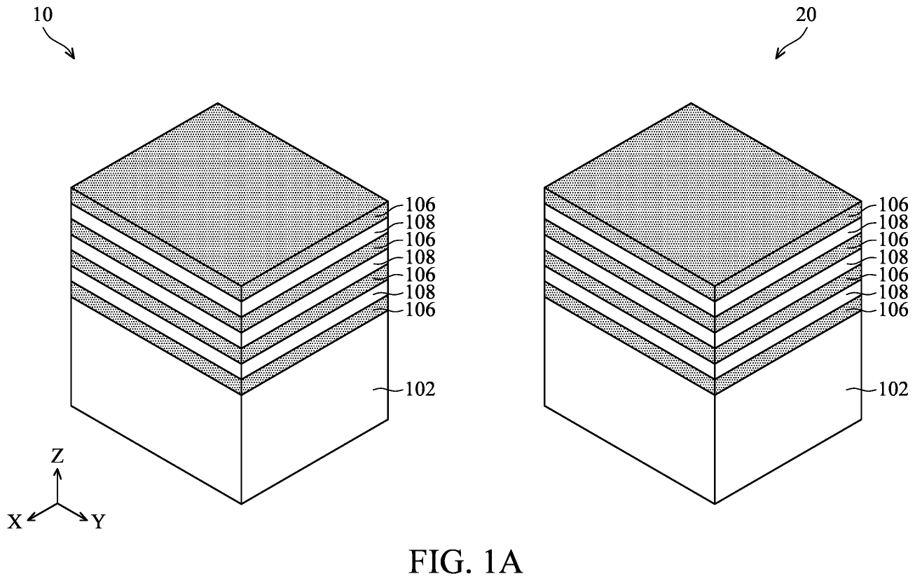

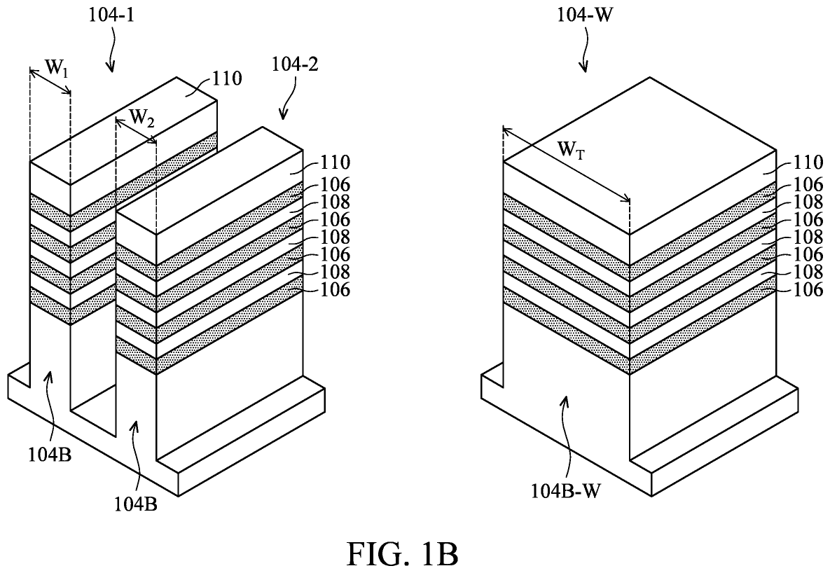

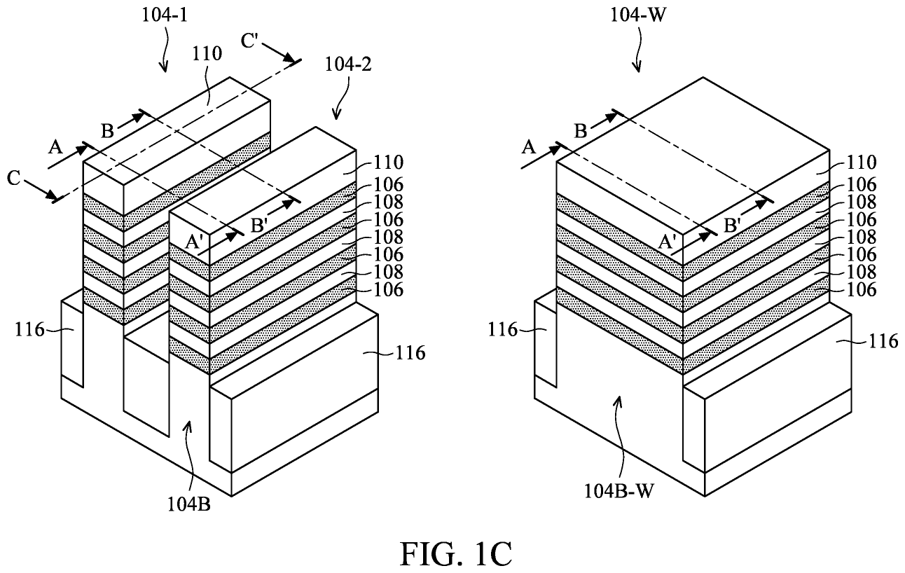

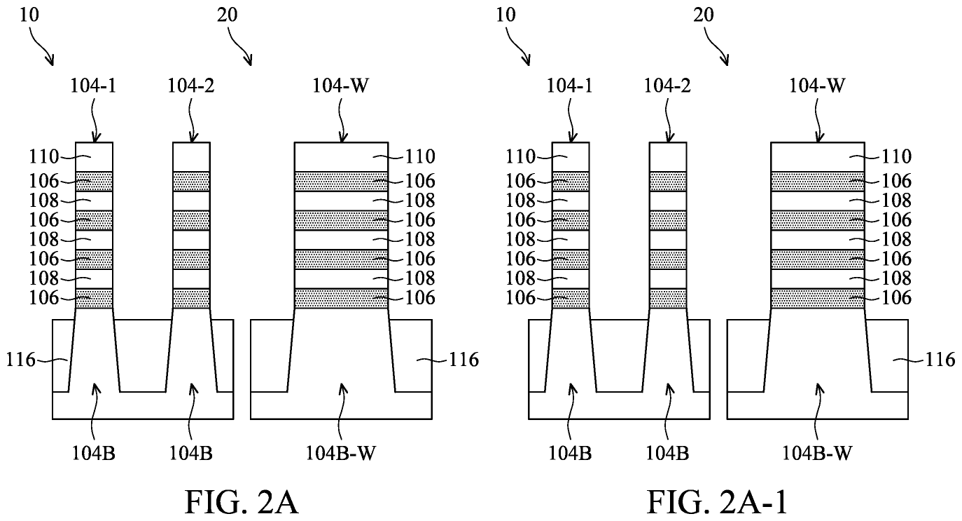

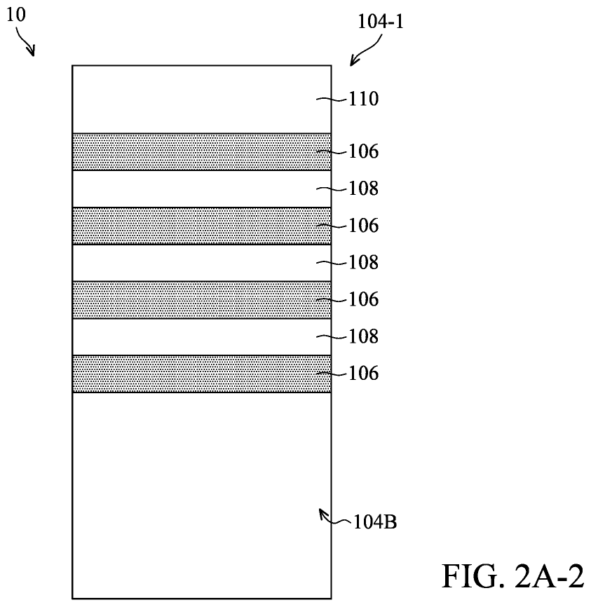

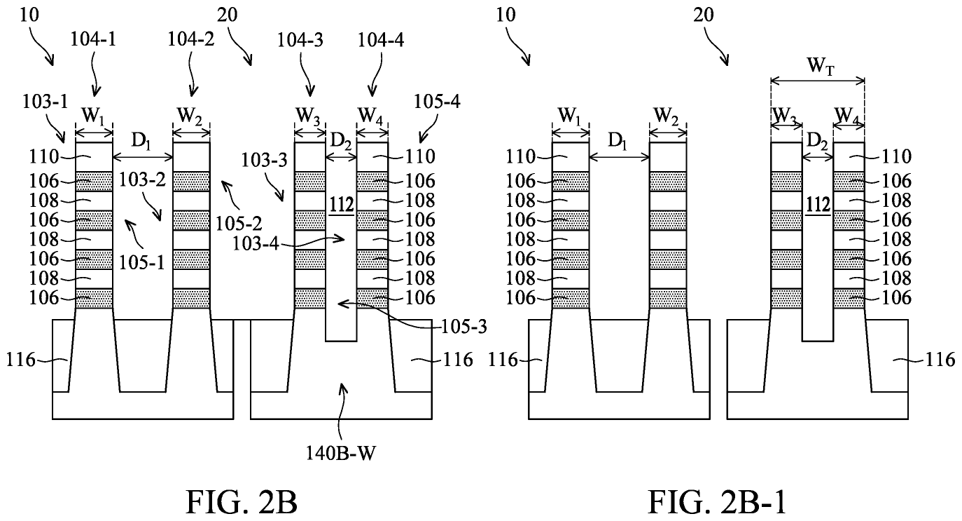

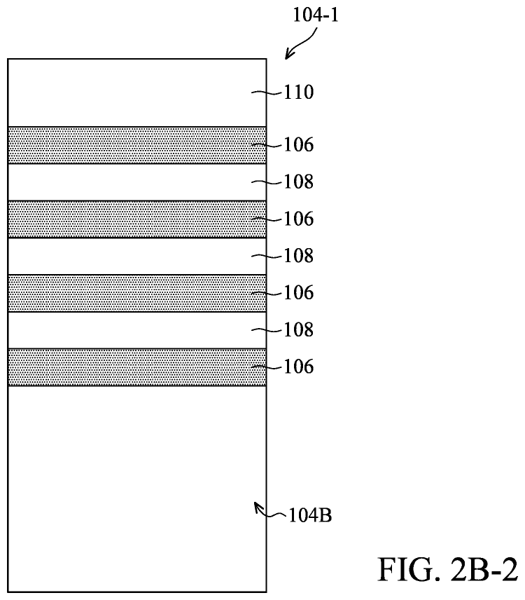

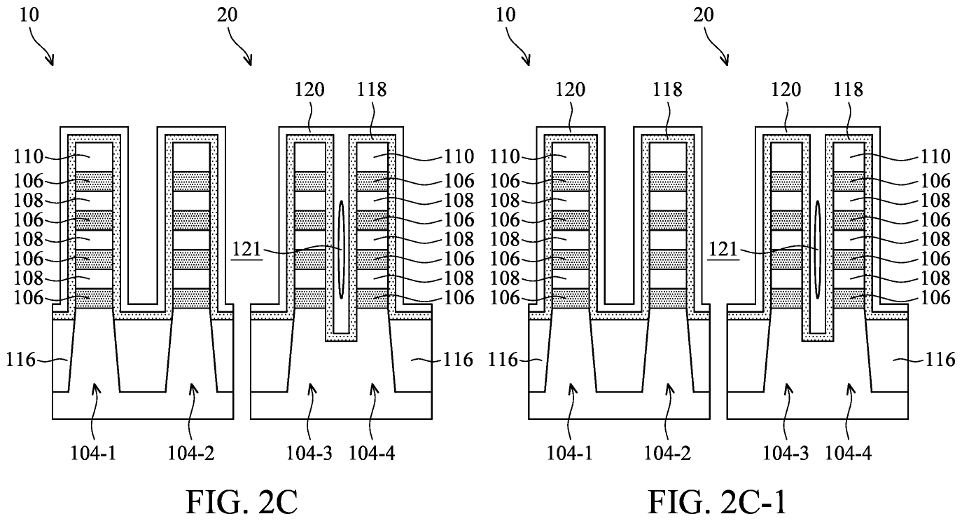

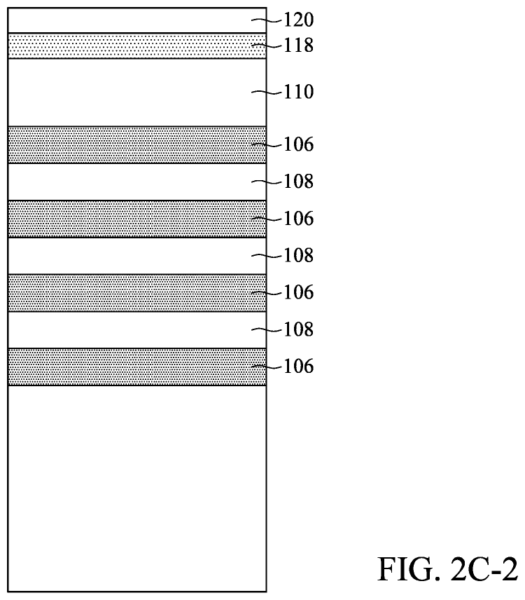

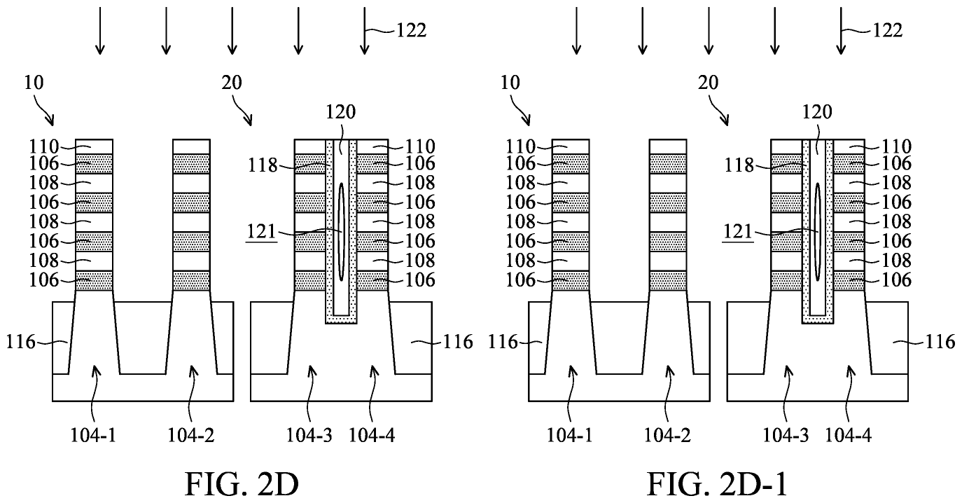

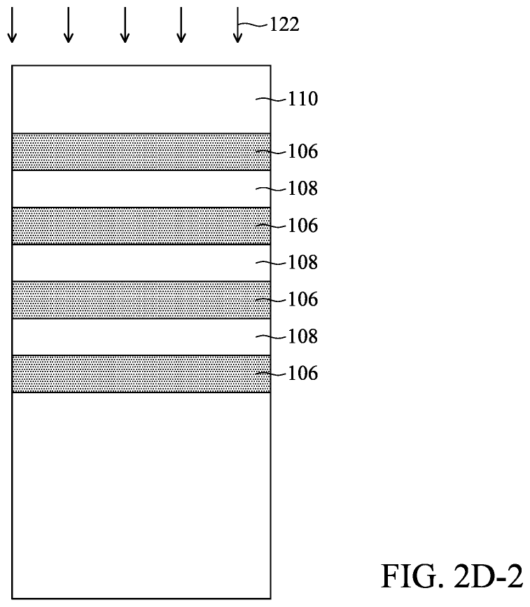

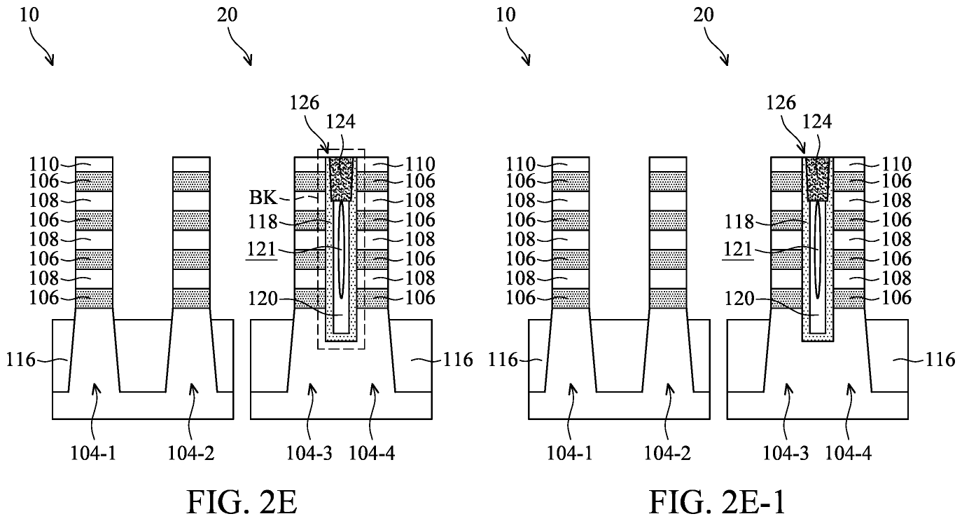

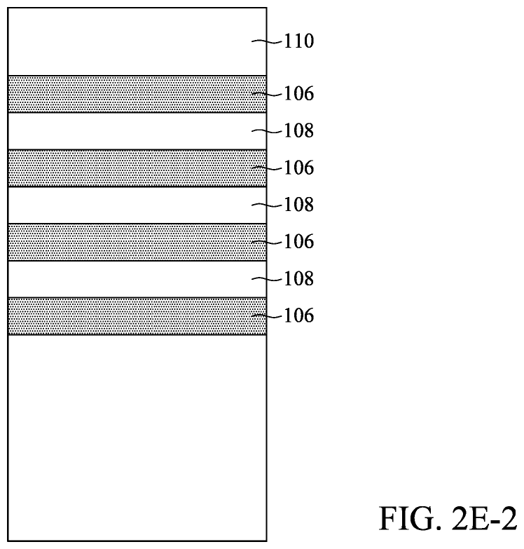

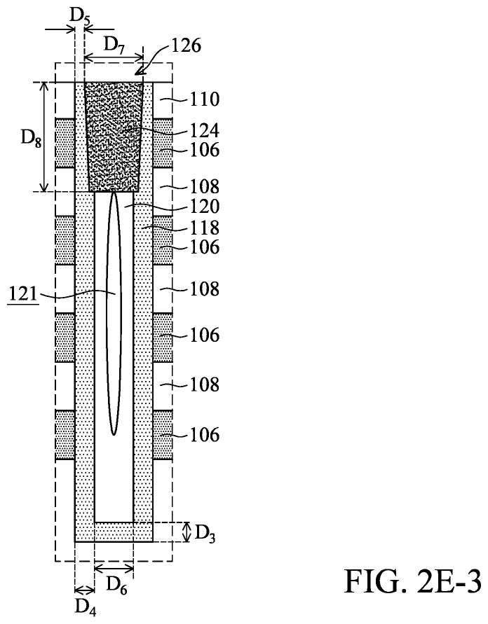

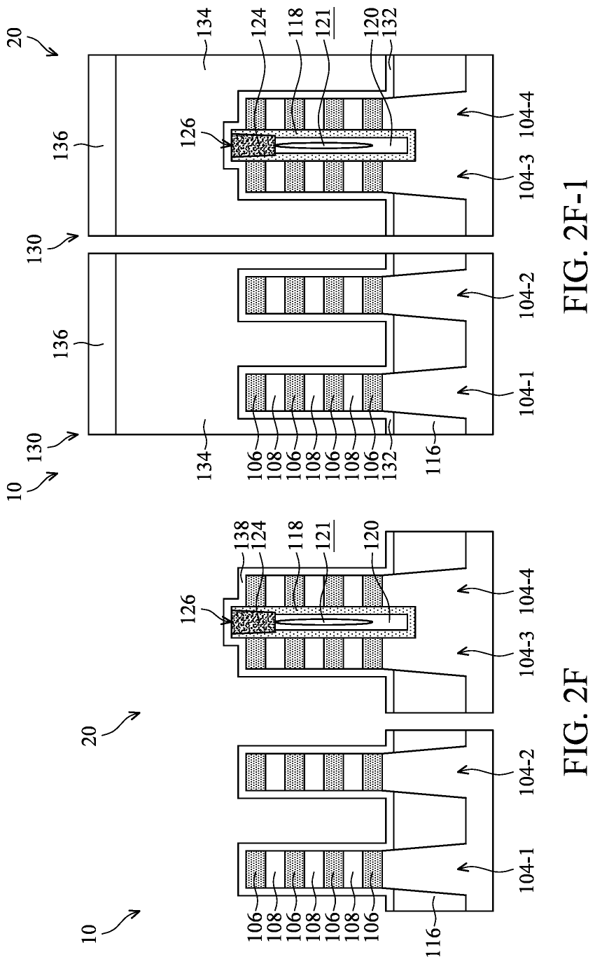

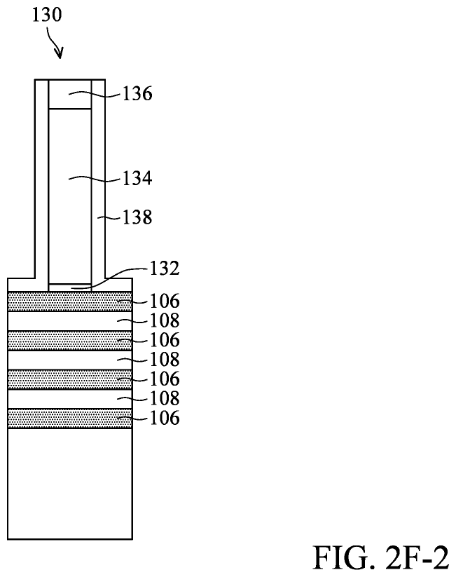

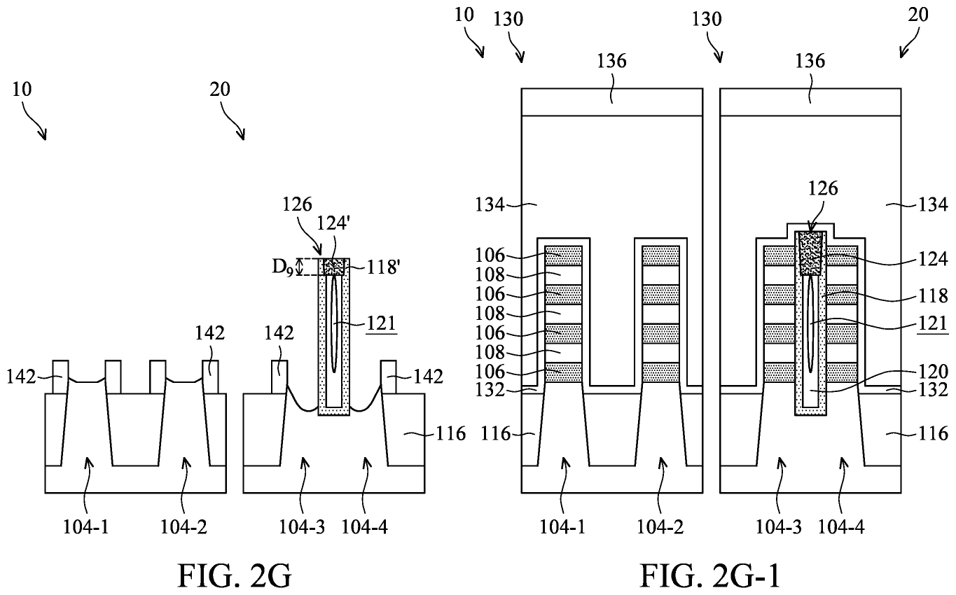

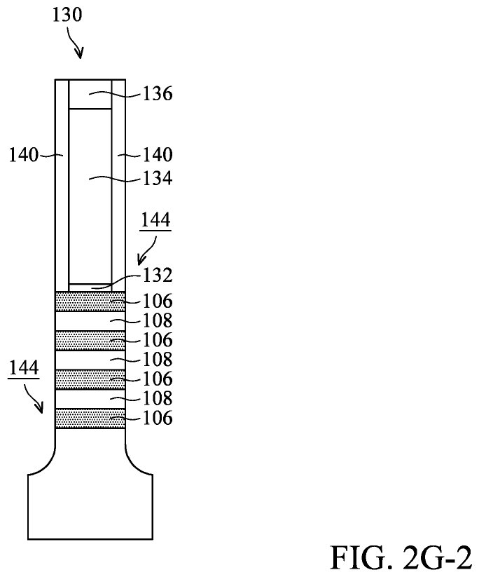

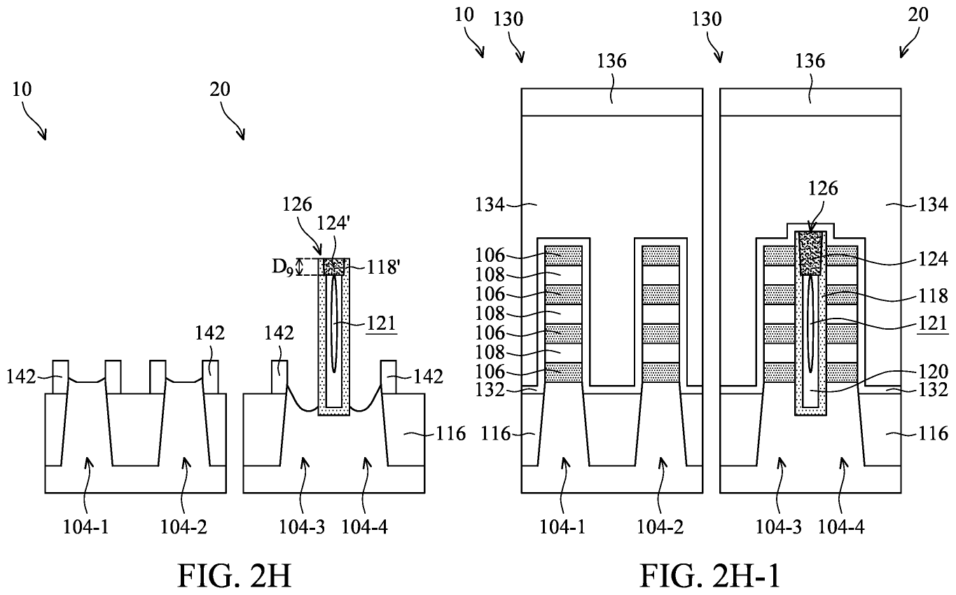

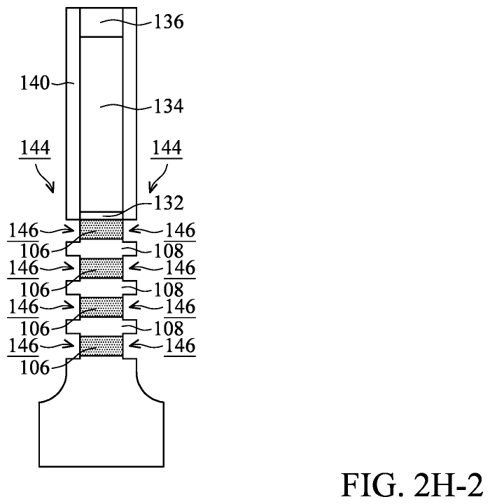

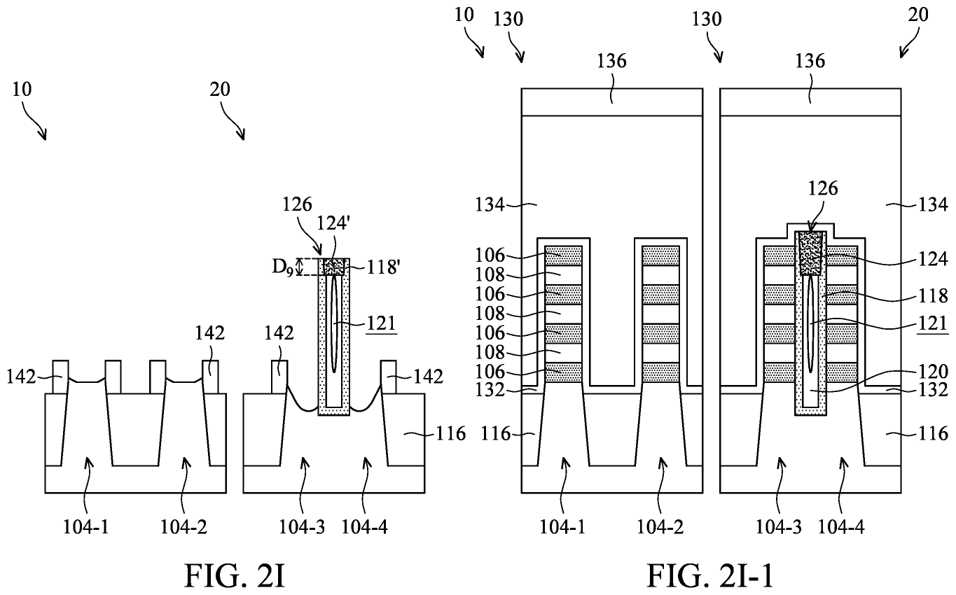

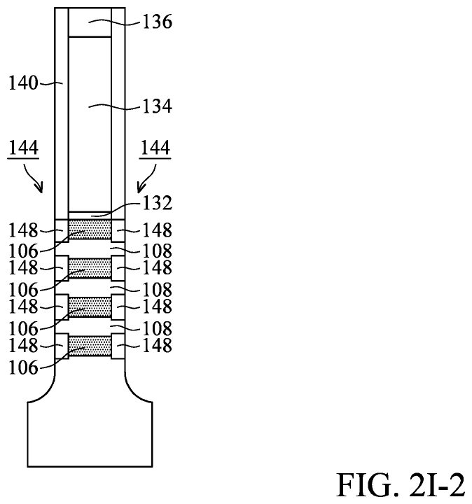

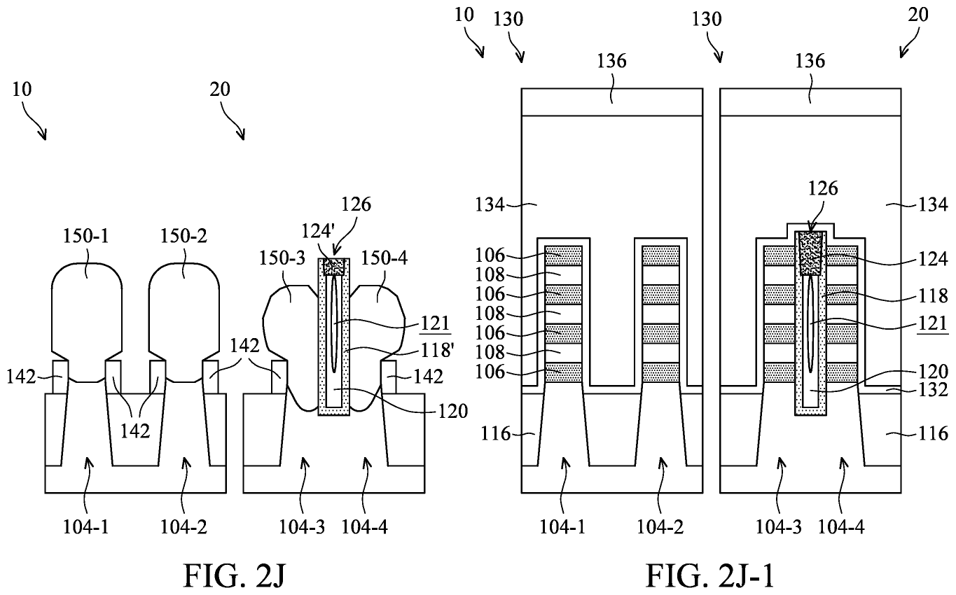

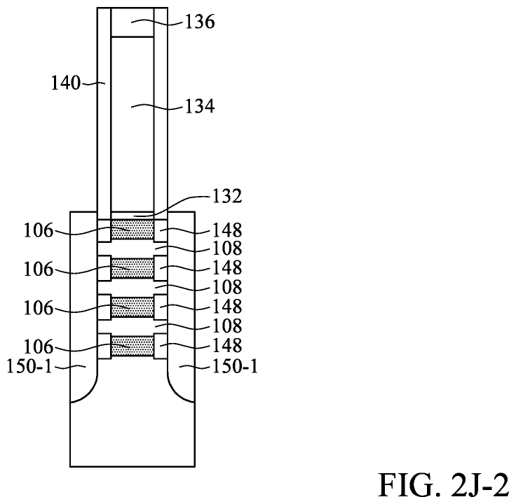

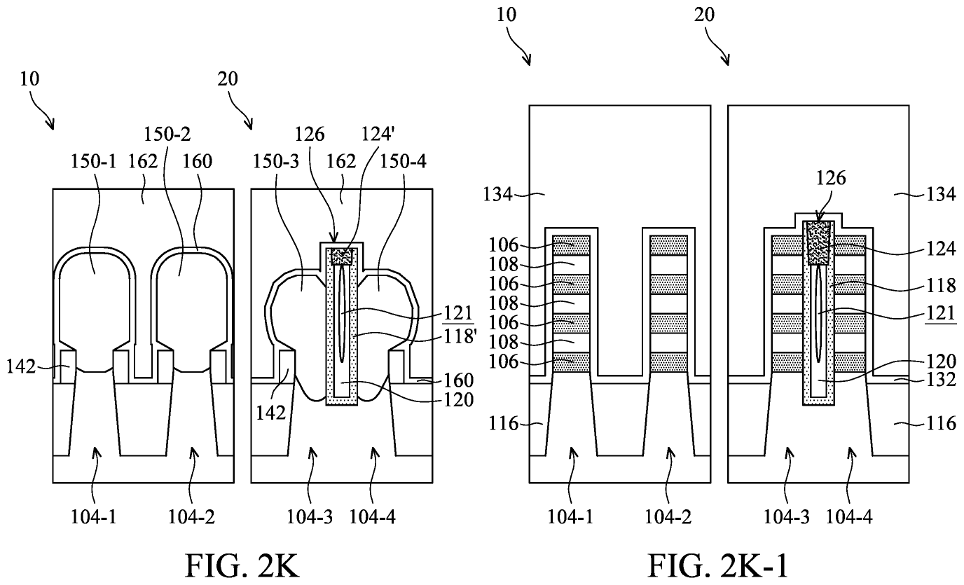

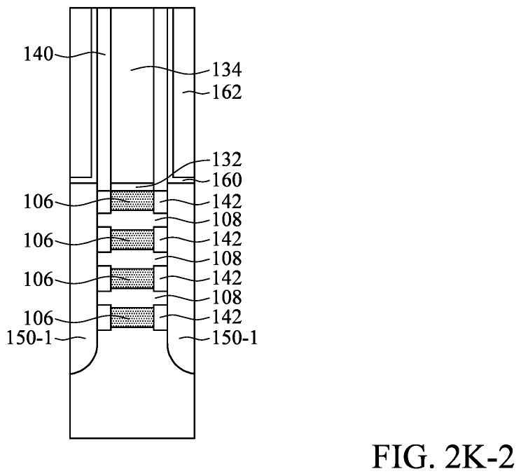

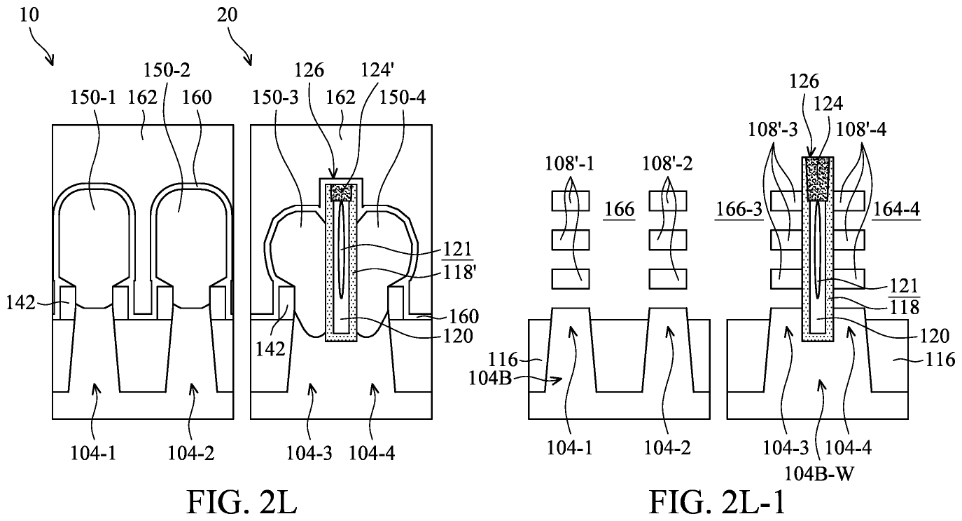

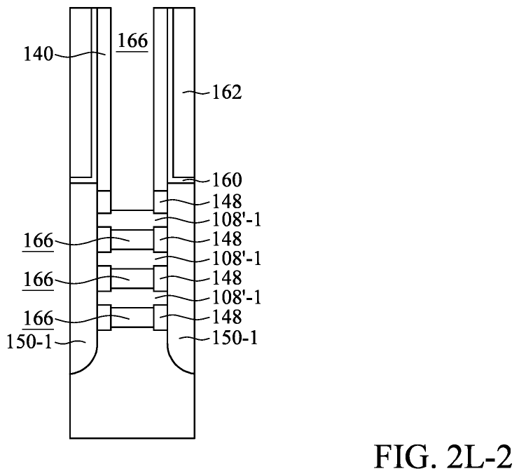

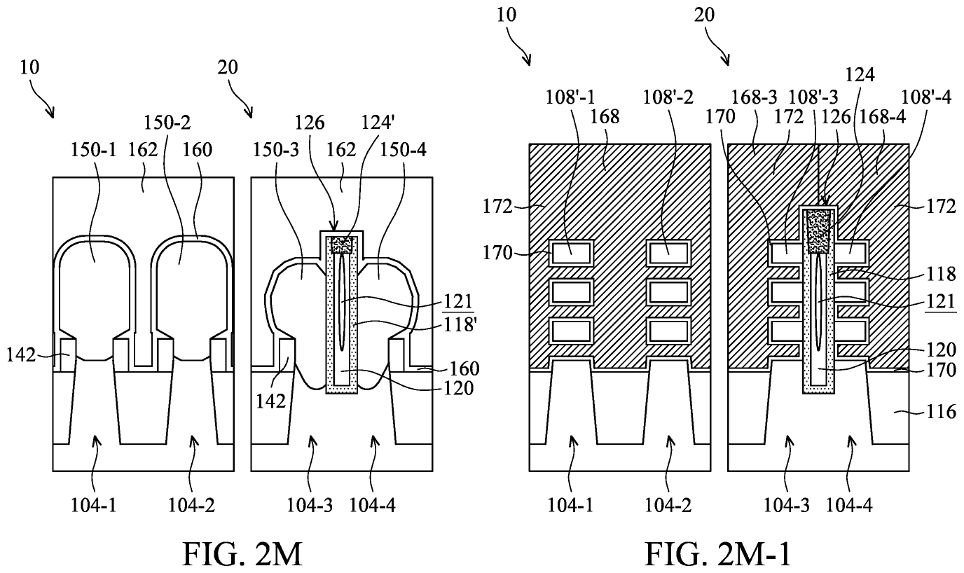

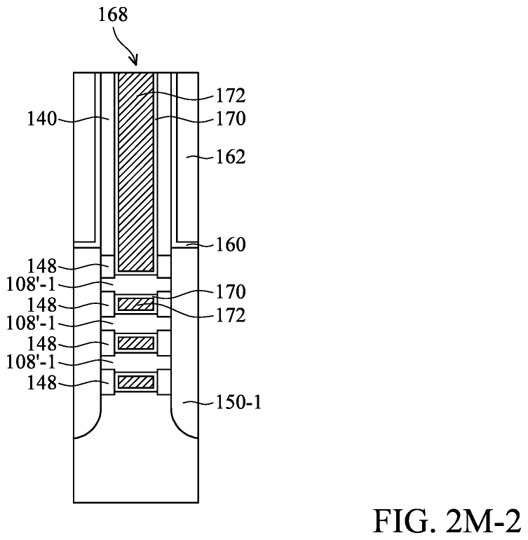

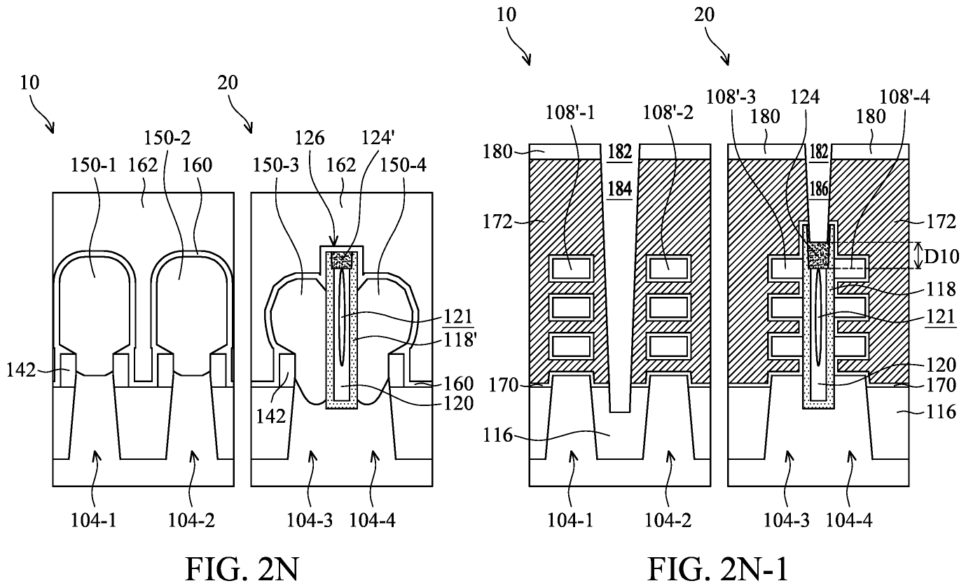

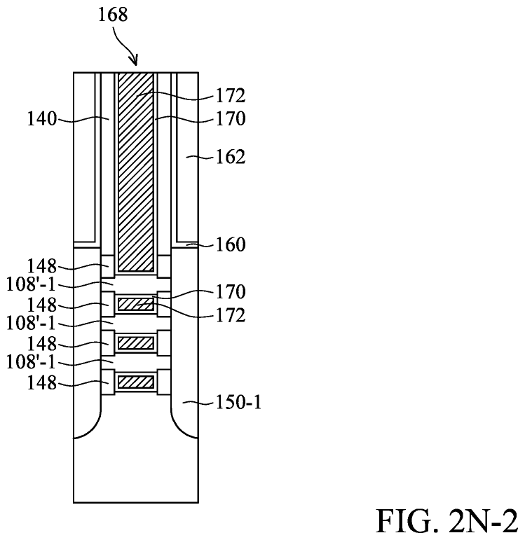

FIGS. 1A to 1C illustrate diagrammatic perspective views of intermediate stages of manufacturing a semiconductor structure 100 in accordance with some embodiments. FIGS. 2A to 2O, 2A-1 to 2O-1, and 2A-2 to 2O-2 illustrate the cross-sectional views of intermediate stages of manufacturing the semiconductor structure 100 shown along line A-A′ (i.e. in the Y direction), B-B′ (i.e. in the Y direction), and C-C′ (i.e. in the X direction) in FIG. 1C, respectively, in accordance with some embodiments. More specifically, FIGS. 2A, 2A-1, and 2A-2 illustrate the cross-sectional views of the intermediate stages of the semiconductor structure 100 shown in FIG. 1C, and FIGS. 2B to 2O, 2B-1 to 2O-1, 2B-2 to 2O-2 illustrate the cross-sectional views of the intermediate stages of manufacturing the semiconductor structure 100 afterwards in accordance with some embodiments.

The semiconductor structure 100 may include multi-gate devices and may be included in a microprocessor, a memory, or other IC devices. For example, the semiconductor structure 100 may be a portion of an IC chip that includes various passive and active microelectronic devices such as resistors, capacitors, inductors, diodes, p-type field effect transistors (PFETs), n-type field effect transistors (NFETs), metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, other applicable components, or combinations thereof.

First, a substrate 102 including a first region 10 and a second region 20 is formed, and a semiconductor stack including first semiconductor material layers 106 and second semiconductor material layers 108 is formed over both the first region 10 and the second region 20 of the substrate 102, as shown in FIG. 1A in accordance with some embodiments. The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

In some embodiments, the first semiconductor material layers 106 and the second semiconductor material layers 108 are alternately stacked over the substrate 102. In some embodiment, the first semiconductor material layers 106 and the second semiconductor material layers 108 are made of different semiconductor materials. In some embodiments, the first semiconductor material layers 106 are made of SiGe, and the second semiconductor material layers 108 are made of silicon. It should be noted that although four first semiconductor material layers 106 and three second semiconductor material layers 108 are shown in FIG. 1A, the semiconductor stack may include less or more of the first semiconductor material layers 106 and the second semiconductor material layers 108 alternately stacked. For example, the semiconductor stack may include two to five of the first semiconductor material layers 106 and two to five of the second semiconductor material layers 108.

The first semiconductor material layers 106 and the second semiconductor material layers 108 may be formed by using low-pressure chemical vapor deposition (LPCVD), epitaxial growth process, another suitable method, or a combination thereof. In some embodiments, the epitaxial growth process includes molecular beam epitaxy (MBE), metal organic chemical vapor deposition (MOCVD), or vapor phase epitaxy (VPE).

After the first semiconductor material layers 106 and the second semiconductor material layers 108 are formed as the semiconductor stack over the substrate 102, the semiconductor stack is patterned to form fin structures 104-1, 104-2, and 104-W, as shown in FIG. 1B in accordance with some embodiments. The fin structures 104-1, 104-2, and 104-W may extend lengthwise along the X direction. In some embodiments, the patterning process includes forming a mask structure 110 over the semiconductor material stack, and etching the semiconductor material stack and the underlying substrate 102 through the mask structure 110. In some embodiments, the mask structure 110 is a multilayer structure including a pad oxide layer and a nitride layer formed over the pad oxide layer. The pad oxide layer may be made of silicon oxide, which is formed by thermal oxidation or CVD, and the nitride layer may be made of silicon nitride, which is formed by CVD, such as LPCVD or plasma-enhanced CVD (PECVD).

In some embodiments, the fin structures 104-1 and 104-2 include base fin structures 104B and the semiconductor stacks, including the first semiconductor material layers 106 and the second semiconductor material layers 108 formed over the base fin structures 104B, and the fin structure 104-W includes a base fin structure 104B-W and the semiconductor stacks, including the first semiconductor material layers 106 and the second semiconductor material layers 108 formed over the base fin structure 104B-W. More specifically, the fin structure 104-1 and 104-2 are formed in the first region 10, and the fin structure 104-W is formed in the second region 20 in accordance with some embodiments. In some embodiments, the fin structure 104-W is wider than the fin structures 104-1 and 104-2. In some embodiments, the fin structure 104-1 has a width W₁ in a range from about 16 nm to about 20 nm, the fin structure 104-2 has a width W₂ in a range from about 16 nm to about 20 nm, and the fin structure 104-W has a width W_{T} in a range from about 55 nm to about 80 nm.

After the fin structures 104-1, 104-2, and 104-W are formed, an isolation structure 116 is formed around the fin structures 104-1, 104-2, and 104-W, as shown in FIGS. 1C, 2A, 2A-1, and 2A-2 in accordance with some embodiments. The isolation structure 116 is configured to electrically isolate active regions (e.g. the fin structures 104-1, 104-2, and 104-W) of the semiconductor structure and is also referred to as shallow trench isolation (STI) feature in accordance with some embodiments.

More specifically, an insulating layer may be formed around and covering the fin structures 104-1, 104-2, and 104-W, and the insulating layer may be recessed to form the isolation structure 116 with the fin structures 104-1, 104-2, and 104-W protruding from the top surface of the isolation structure 116. In some embodiments, the insulating layer is made of silicon oxide, silicon nitride, silicon oxynitride (SiON), another suitable insulating material, or a combination thereof. In addition, liner layers (not shown) may be formed before forming the insulating layer, and the liner layers may also be recessed with the insulating layer to form the isolation structure 116. In some embodiments, the liner layers include multiple dielectric material layers.

After the isolation structure 116 is formed, the fin structure 104-W is patterned to form fin structures 104-3 and 104-4, as shown in FIGS. 2B, 2B-1, and 2B-2 in accordance with some embodiments. More specifically, a recess 112 is formed through the semiconductor stack of the fin structure 104-W and extends into the base fin structure 104B-W, in accordance with some embodiments. In some embodiments, the bottom surface of the recess 112 is lower than the top surface of the isolation structure 116.

The fin structures 104-1, 104-2, 104-3, and 104-4 may include sidewalls 103-1, 103-2, 103-3, and 103-4 facing a first side and sidewalls 105-1, 105-2, 105-3, and 105-4 facing a second side opposite the first side. In some embodiments, the distance D₁ between the sidewall 105-1 of the fin structure 104-1 and the sidewall 103-2 of the fin structure 104-2 is greater than the distance D₂ between the sidewall 105-3 of the fin structures 104-3 and the sidewall 103-4 of the fin structure 104-4. In some embodiments, the distance D₂ is in a range from about 15 nm to about 25 nm. In some embodiments, the difference between the distances D₁ and D₂ is greater than 5 nm. The distance D₂ and the difference between the distances D₁ and D₂ may be controlled, so that an isolation feature may be formed in the recess 112 without complicated patterning process (the details will be described later).

After the fin structure 104-W is patterned, a dielectric wall structure may be formed between the fin structures 104-3 and 104-4. More specifically, a dielectric shell layer 118 is conformally formed to cover the fin structures 104-1, 104-2, 104-3, and 104-4 and the isolation structure 116, and a core portion 120 is formed over the dielectric shell layer 118, as shown in FIGS. 2C, 2C-1, and 2C-2 in accordance with some embodiments.

The dielectric shell layer 118 is configured protect the dielectric wall structure in subsequent etching process. In some embodiments, the dielectric shell layer 118 covers the sidewalls and the top surfaces of the fin structures 104-1, 104-2, 104-3, and 104-4 and the top surface of the isolation structure 116. In some embodiments, the dielectric shell layer 118 is made of a nitride base dielectric materials such as SiN. In some embodiments, the dielectric shell layer 118 has a thickness in a range from about 3 nm to about 5 nm.

In some embodiments, the core portion 120 is made of a low k dielectric material, so that the capacitance of the resulting semiconductor device may be reduced. In some embodiments, the core portion 120 is made of an oxide base dielectric material, an oxynitride base dielectric material, or a flowable base dielectric material, such as SiO₂. In some embodiments, the core portion 120 and the isolation structure 116 are made of the same material. The dielectric shell layer 118 and the core portion 120 may be deposited using CVD, PVD, ALD, HDPCVD, MOCVD, RPCVD, PECVD, LPCVD, ALCVD, APCVD, other applicable methods, or combinations thereof.

In some embodiments, the space between the fin structures 104-3 and 104-4 is substantially filled with the dielectric shell layer 118 and the core portion 120, while the space between the fin structures 104-1 and 104-2 is not completely filled with the dielectric shell layer 118 and the core portion 120. In some embodiments, a void 121 is formed in the core portion 120.

Next, an etching process 122 is performed, as shown in FIGS. 2D, 2D-1, and 2D-2 in accordance with some embodiments. In some embodiments, the etching process 122 is performed without using a mask structure. During the etching process 122, since the recess 122 is completely filled by the core portion 120 and the dielectric shell layer 118, the removal of the core portion 120 and the dielectric shell layer 118 in the recess 118 may be much slower than that in other places. That is, the removal of the core portion 120 and the dielectric shell layer 118 in other regions (e.g. over the sidewalls 103-1, 105-1, 103-2, 105-2, 103-3, and 105-4 of the fin structures 104-1, 104-2, 104-3, and 104-4) is much easier than the removal of the core portion 120 and the dielectric shell layer 118 in the recess 118, since the top and sidewall surfaces of the core portion 120 are largely exposed. Therefore, the core portion 120 and the dielectric shell layer 118 formed in the wider space can be completely removed, while the core portion 120 and the dielectric shell layer 118 formed in the recess 112 are only partially removed during the etching process without performing complicated patterning process. The remaining core portion 120 and the dielectric shell layer 118 form the bottom portion of the dielectric wall structure in accordance with some embodiments. In some other embodiments, the core portion 120 and the dielectric shell layer 118 in the recess 112 are also etched during the etching process 122. In some embodiments, the mask structures 110 formed over the fin structures 104-1, 104-2, 104-3, and 104-4 are also partially etched during the etching process 122. That is, the heights of the mask structures 110 are reduced after the etching process 122 is performed in accordance with some embodiments.

Next, the dielectric shell layer 118 and the core portion 120 are recessed to form a recess in the upper region of the recess 112, and a cap layer 124 is formed in the recess, as shown in FIGS. 2E, 2E-1, and 2E-2 in accordance with some embodiments. In some embodiments, the dielectric shell layer 118 and the core portion 120 are recessed by performing an etching process. In some embodiments, the etching process is an isotropic etching such as dry chemical etching, remote plasma etching, wet chemical etching, other applicable technique, and/or a combination thereof. During the etching process, the etching rate of the core portion 120 is higher than the etching rate of the dielectric shell layer 118, so that some portions of the dielectric shell layer 118 may still remain on the upper portion of the sidewalls 105-3 and 103-4 of the fin structures 104-3 and 104-4, while the upper portion of the core portion are completely removed in accordance with some embodiments. In some other embodiments, the bottom surface of the recess is lower than the topmost surface of the second semiconductor material layers 108 and is higher than the bottom surface of the topmost layer of the second semiconductor material layers 108. In some other embodiments, the bottom surface of the recess is substantially level with the topmost surface of the second semiconductor material layers 108. In some other embodiments, the bottom surface of the recess is higher than the topmost surface of the second semiconductor material layers 108 and is lower than the topmost surface of the first semiconductor material layers 106.

After the etching process is performed, the cap layer 124 is formed to form a dielectric wall structure 126, as shown in FIGS. 2E, 2E-1, and 2E-2 in accordance with some embodiments. More specifically, the dielectric wall structure 126 is sandwiched between the fin structures 104-3 and 104-4 over the base fin structure 104B-W in accordance with some embodiments. In addition, the dielectric wall structure 126 includes the dielectric shell layer 118 covering the sidewalls 105-3 and 103-4, the core portion 120 formed over the dielectric shell layer 118, and the cap layer 124 formed over the core portion 120 and the dielectric shell layer 118 in accordance with some embodiments.

In some embodiments, the cap layer 124 is made of the carbon-containing (e.g. rich) nitride, Hf-containing (e.g. Hf-base), Zr-containing (e.g. Zr-base), or Al-containing (e.g. Al-base) metal oxide, or doped oxide. In some embodiments, the cap layer 124 is made of HfO2 or ZrO2. In some embodiments, the cap layer 124 is doped with Si.

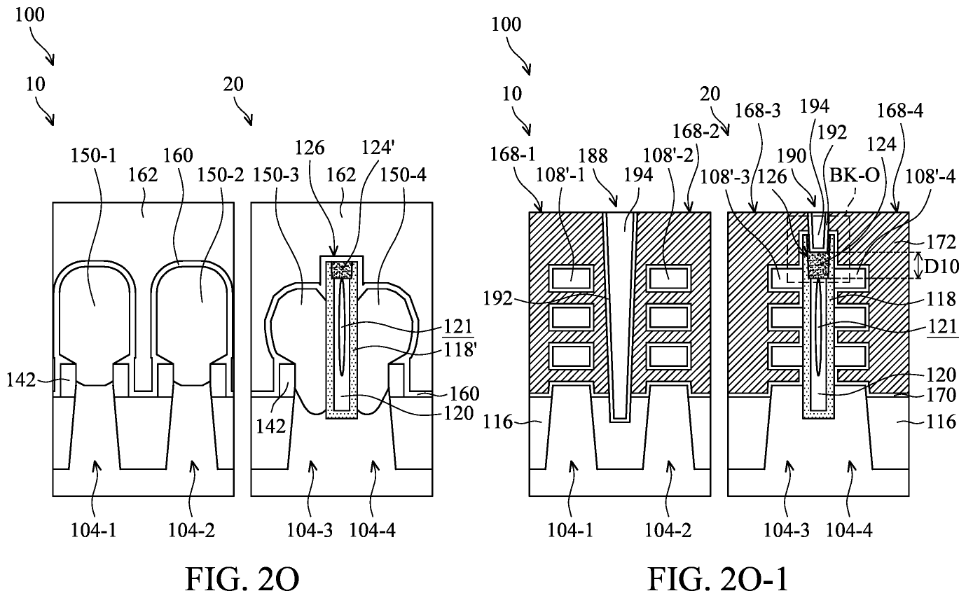

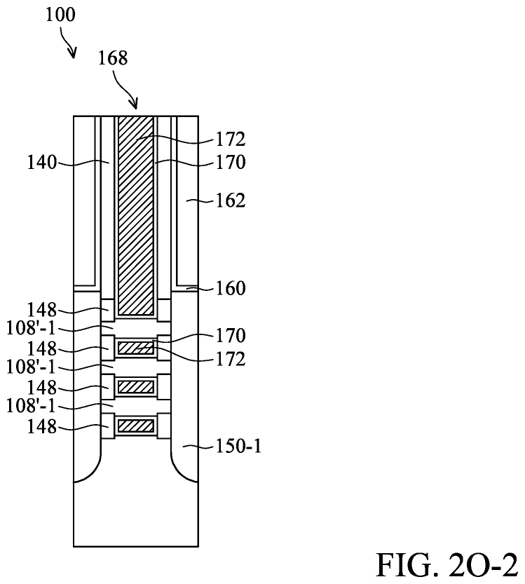

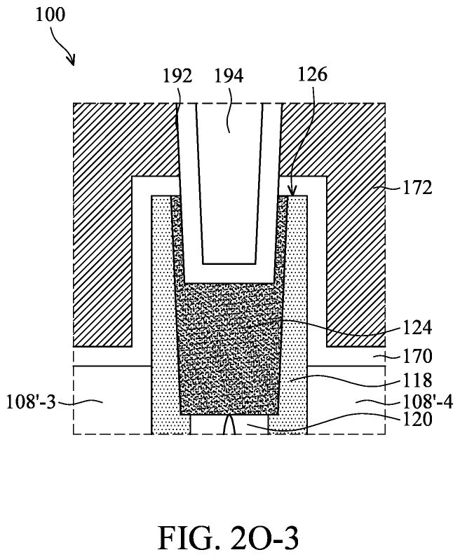

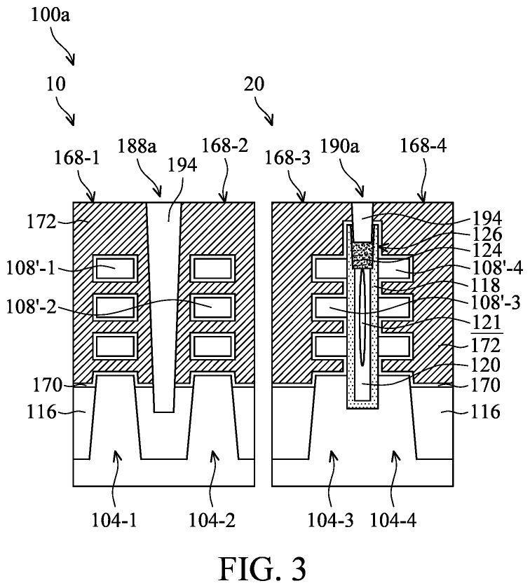

FIG. 2E-3 illustrates an enlarged cross-sectional view of the semiconductor structure shown in the block BK of FIG. 2E in accordance with some embodiments. In some embodiments, the dielectric shell layer 118 includes a bottom portion vertically below the core portion 120, a sidewall portion laterally surrounding the core portion 120, and an extending portion laterally surrounding the cap layer 124. The bottom portion may have a dimension D₃ along the Z direction, the sidewall portion may have a dimension D₄ along the Y direction. In some embodiments, the dimension D₃ is greater than the dimension D₄. In addition, the extending portion may have a dimension D₅ along the Y direction, and the dimension D₅ is smaller than the dimension D₄ in accordance with some embodiments. In some embodiments, the dimension D₅ is smaller than 5 nm.

Furthermore, the core portion 120 may have a dimension D₆ at its bottom surface along the Y direction, and the cap layer 124 may have a dimension D₇ at its top surface along the Y direction. Since the extending portion of the dielectric shell layer 118 is thinner than its sidewall portion, the dimension D₇ is greater than the dimension D₆ in accordance with some embodiments. In some embodiments, the width of the cap layer 124 along the Y direction gradually decreases from its top surface to its bottom surface. In some embodiments, the dimension D₇ is in a range from about 15 nm to about 30 nm. In some embodiments, the cap layer 124 has a dimension D₈ along Z direction in a range from about 20 nm to about 30 nm.

Afterwards, a dummy gate structure 130 is formed across the fin structures 104-1, 104-2, 104-3, and 104-4 and the dielectric wall structure 126, as shown in FIGS. 2F, 2F-1, and 2F-2 in accordance with some embodiments. The dummy gate structure 130 may be used to define the channel regions of the resulting semiconductor structure 100.

In some embodiments, the dummy gate structure 130 includes a dummy gate dielectric layer 132 and a dummy gate electrode layer 134. In some embodiments, the dummy gate dielectric layer 132 is made of one or more dielectric materials, such as silicon oxide, silicon nitride, silicon oxynitride (SiON), HfO₂, HfZrO, HfSiO, HfTiO, HfAlO, or a combination thereof. In some embodiments, the dummy gate dielectric layer 132 is formed using thermal oxidation, CVD, ALD, physical vapor deposition (PVD), another suitable method, or a combination thereof.

In some embodiments, the dummy gate electrode layer 134 is made of conductive material includes polycrystalline-silicon (poly-Si), poly-crystalline silicon-germanium (poly-SiGe), or a combination thereof. In some embodiments, the dummy gate electrode layer 134 is formed using CVD, PVD, or a combination thereof.

In some embodiments, a hard mask layer 136 is formed over the dummy gate electrode layer 134. In some embodiments, the hard mask layer 136 includes multiple layers, such as an oxide layer and a nitride layer. In some embodiments, the oxide layer is silicon oxide, and the nitride layer is silicon nitride.

The formation of the dummy gate structures 130 may include conformally forming a dielectric material as the dummy gate dielectric layers 132. Afterwards, a conductive material may be formed over the dielectric material as the dummy gate electrode layers 134, and the hard mask layer 136 may be formed over the conductive material. Next, the dielectric material and the conductive material may be patterned through the hard mask layer 136 to form the dummy gate structures 130.

After the dummy gate structure 130 is formed, a spacer layer 138 is formed to cover the top surfaces and the sidewalls of the dummy gate structures 130 and the fin structures 104-1, 104-2, 104-3, and 104-4, as shown in FIGS. 2F, 2F-1, and 2F-2 in accordance with some embodiments. In some embodiments, the spacer layer 138 is made one or more dielectric materials. The dielectric materials may include silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof.

After the spacer layer 138 is formed, an etching process is performed to form gate spacers 140 and fin spacers 142 and source/drain recesses 144, as shown in FIGS. 2G, 2G-1, and 2G-2 in accordance with some embodiments. The gate spacers 140 may be configured to separate source/drain structures (formed afterwards) from the dummy gate structure 130, and the fin spacers 142 may be configured to confine the growth of the source/drain structures formed therein.

More specifically, the spacer layer 138 is etched to form the gate spacers 140 on opposite sidewalls of the dummy gate structure 130 and to form the fin spacers 142 covering the sidewalls of the fin structures 104-1 to 104-4 in accordance with some embodiments. In addition, the portions of the fin structures 104-1 to 104-4 not covered by the dummy gate structure 130 and the gate spacers 140 are etched to form the source/drain recesses 144 during the etching process in accordance with some embodiments. The etching process may be an anisotropic etching process, such as dry plasma etching, and the dummy gate structure 130 and the gate spacers 140 may be used as etching masks during the etching process. In some embodiments, the isolation structure 112 is also slightly etched during the etching process.

In some embodiments, during the etching process for forming the source/drain recesses 144, the cap layer 124 and the dielectric shell layer 118 at the source/drain regions are also slightly etched to form recessed cap layer 124′ and recessed dielectric shell layer 118′ at the source/drain region, as shown in FIG. 2G. In some embodiments, the thickness of the cap layer 124 reduced for about 5 nm to about 10 nm. In some embodiments, the recessed cap layer 124′ has a dimension D₉ in a range from about 5 nm to about 15 nm. The remaining portions of the recessed cap layer 124′ and the recessed dielectric shell layer 118′ may be used as protection layers of the bottom portions of the dielectric wall structure 126 during subsequent etching processes.

After the source/drain recesses 144 are formed, the first semiconductor material layers 106 exposed by the source/drain recesses 144 are laterally recessed to form notches 146, as shown in FIGS. 2H, 2H-1, and 2H-2 in accordance with some embodiments. In some embodiments, an etching process is performed to laterally recess the first semiconductor material layers 106 of the fin structure 104-1, 104-2, 104-3, and 104-4 from the source/drain recesses 144. In some embodiments, during the etching process, the first semiconductor material layers 106 have a greater etching rate (or etching amount) than the second semiconductor material layers 108, thereby forming notches 146 between the adjacent second semiconductor material layers 108. In some embodiments, the second semiconductor material layers 108 are also slightly etched during the etching process, so that the portions of the second semiconductor material layers 108 exposed by the notches 146 become thinner than other portions, as shown in FIG. 2H-2 in accordance with some embodiments. In some embodiments, the etching process is an isotropic etching such as dry chemical etching, remote plasma etching, wet chemical etching, another suitable technique, and/or a combination thereof.

Next, inner spacers 148 are formed in the notches 146 between the second semiconductor material layers 108, as shown in FIGS. 2I, 2I-1, and 2I-2 in accordance with some embodiments. The inner spacers 148 may be configured to separate the source/drain structures and the gate structures formed in subsequent manufacturing processes. As described previously, since the second semiconductor material layers 108 are also partially etched when forming the notches 146, the inner spacers 148 formed in the notches 146 are thicker than the thicknesses of the first semiconductor material layers 106 in accordance with some embodiments. In addition, the inner spacers 148 have curve sidewalls in accordance with some embodiments. In some embodiments, the inner spacers 148 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof.

After the inner spacers 148 are formed, source/drain structures 150-1, 150-2, 150-3, and 150-4 are formed in the source/drain recesses 144 of the fin structures 104-1, 104-2, 104-3, and 104-4 respectively, as shown in FIGS. 2J, 2J-1, and 2J-2 in accordance with some embodiments. The source/drain structures described below may refer to a source or a drain, individually or collectively dependent upon the context.

In some embodiments, the source/drain structures 150-1 and 150-2 and the source/drain structures 150-3 and 150-4 have different shapes. More specifically, the source/drain structures 150-1 and 150-2 are formed over the fin structures 104-1 and 104-2 and are sandwiched between the fin spacers 142 in accordance with some embodiments. Since both sides of the source/drain structures 150-1 and 150-2 are confined by the fin spacers 142, the source/drain structures 150-1 and 150-2 have substantially symmetry shapes in the cross-sectional view along the Y direction in accordance with some embodiments. On the other hand, the source/drain structures 150-3 and 150-4 are sandwiched between one fin spacer 142 and the dielectric wall structure 126 with the dielectric wall structure 126 being higher than the fin spacer 142 in accordance with some embodiments. Therefore, the source/drain structures 150-3 and 150-4 have asymmetry shapes in the cross-sectional view in the Y direction in accordance with some embodiments. The source/drain structure 150-3 has a first side and a second side opposite the first side and has a substantially straight sidewall at the second side in accordance with some embodiments. The substantially straight sidewall of the source/drain structure 150-3 is in direct contact with a first sidewall of the dielectric wall structure 126 and is substantially aligned with the sidewall 105-3 of the fin structure 104-3. On the other hand, a sidewall of the source/drain structure 150-3 at the first side extends laterally outside the sidewall 103-3 of the fin structure 104-3 and further extends outside the sidewalls of the fin spacers 142 in accordance with some embodiments.

Similarly, the source/drain structure 150-4 has a first side and a second side opposite the first side. In some embodiments, a substantially straight sidewall of the source/drain structure 150-4 at the first side is in direct contact with a second sidewall of the dielectric wall structure 126 and is substantially aligned with the sidewall 103-4 of the fin structure 104-4. On the other hand, a sidewall of the source/drain structure 150-4 at the second side extends laterally outside the sidewall 105-4 of the fin structure 104-4 and further extends outside the sidewalls of the fin spacers 142 in accordance with some embodiments.

In some embodiments, the top surface of the dielectric wall structure 126 is higher than the topmost portions of the source/drain structures 150-1, 150-2, 150-3, and 150-4. In some embodiments, the topmost portions of the source/drain structures 150-1 and 150-2 are higher than the topmost portions of the source/drain structures 150-3 and 150-4. In some embodiments, the source/drain structures 150-1, 150-2, 150-3, and 150-4 are all substantially the same height.

In some embodiments, the source/drain structures 150-1, 150-2, 150-3, and 150-4 are formed using an epitaxial growth process, such as MBE, MOCVD, VPE, other applicable epitaxial growth process, or a combination thereof. In some embodiments, the source/drain structures 150-1, 150-2, 150-3, and 150-4 are made of any applicable material, such as Ge, Si, GaAs, AlGaAs, SiGe, GaAsP, SiP, SiC, SiCP, or a combination thereof. In some embodiments, the source/drain structures 150-1, 150-2, 150-3, and 150-4 are in-situ doped during the epitaxial growth process. For example, the source/drain structures 150-1, 150-2, 150-3, and 150-4 may be the epitaxially grown SiGe doped with boron (B). For example, the source/drain structures 150-1, 150-2, 150-3, and 150-4 may be the epitaxially grown Si doped with carbon to form silicon:carbon (Si:C) source/drain features, phosphorous to form silicon:phosphor (Si:P) source/drain features, or both carbon and phosphorous to form silicon carbon phosphor (SiCP) source/drain features. In some embodiments, the source/drain structures 150-1, 150-2, 150-3, and 150-4 are doped in one or more implantation processes after the epitaxial growth process.

After the source/drain structures 150-1, 150-2, 150-3, and 150-4 are formed, a contact etch stop layer (CESL) 160 is conformally formed to cover the source/drain structures 150-1, 150-2, 150-3, and 150-4, and an interlayer dielectric (ILD) layer 162 is formed over the contact etch stop layers 160, as shown in FIGS. 2K, 2K-1, and 2K-2 in accordance with some embodiments. In some embodiments, the contact etch stop layer 160 is in direct contact with the sidewalls of the dielectric shell layers 118 and the top surface of the cap layer 124 of the dielectric wall structures 126.

In some embodiments, the contact etch stop layer 160 is made of a dielectric materials, such as silicon nitride, silicon oxide, silicon oxynitride, another suitable dielectric material, or a combination thereof. The dielectric material for the contact etch stop layers 160 may be conformally deposited over the semiconductor structure by performing CVD, ALD, other application methods, or a combination thereof.

The interlayer dielectric layer 162 may include multilayers made of multiple dielectric materials, such as silicon oxide, silicon nitride, silicon oxynitride, phosphosilicate glass (PSG), borophosphosilicate glass (BPSG), or other applicable low-k dielectric materials. The interlayer dielectric layer 162 may be formed by chemical vapor deposition (CVD), physical vapor deposition, (PVD), atomic layer deposition (ALD), or other applicable processes.

After the contact etch stop layer 160 and the interlayer dielectric layer 162 are deposited, a planarization process such as CMP or an etch-back process is performed until the dummy gate electrode layer 134 is exposed, as shown in FIGS. 2K-1 and 2K-2 in accordance with some embodiments.

Next, the dummy gate structures 130 and the first semiconductor material layers 106 are removed to form gate trenches 166, 166-3, and 166-4, as shown in FIGS. 2L, 2L-1, and 2L-2 in accordance with some embodiments. More specifically, the dummy gate structures 130 and the first semiconductor material layers 106 are removed to form channel structures (e.g. nanostructures) 108′-1, 108′-2, 108′-3, and 108′-4 with the second semiconductor material layers 108 of the fin structures 104-1, 104-2, 104-3, and 104-4 respectively in accordance with some embodiments. Although not clearly shown in the figures, the channel structures 108′-1, 108′-2, 108′-3, and 108′-4 and the base fin structures 104B and 104B-W may have rounded corners.

The removal process may include one or more etching processes. For example, when the dummy gate electrode layer 134 may be made of polysilicon, a wet etchant such as a tetramethylammonium hydroxide (TMAH) solution may be used to selectively remove the dummy gate electrode layer 134. Afterwards, the dummy gate dielectric layer 132 may be removed using a plasma dry etching, a dry chemical etching, and/or a wet etching. The first semiconductor material layers 106 may be removed by performing a selective wet etching process, such as APM (e.g., ammonia hydroxide-hydrogen peroxide-water mixture) etching process. For example, the wet etching process uses etchants such as ammonium hydroxide (NH₄OH), TMAH, ethylenediamine pyrocatechol (EDP), and/or potassium hydroxide (KOH) solutions.

As shown in FIG. 2L-1, the top surface, the bottom surface, and the two sidewalls of each of the channel structures 108′-1 and 108′-2 in the channel region are fully exposed by the gate trench 166 in accordance with some embodiments. On the other hand, although the top surface and the bottom surface of each of the channel structures 108′-2 and 108′-4 are also exposed by the gate trenches 166-3 and 166-4 respectively, only one sidewall of each of the channel structures 108′-2 and 108′-4 is exposed by the gate trenches 166-3 and 166-4 in the cross-sectional view along the Y direction in accordance with some embodiments. That is, one sidewall of each of the channel structures 108′-3 and 108′-4 is attached to the dielectric wall structure 126 and is not exposed by the gate trenches 166-3 and 166-4 in accordance with some embodiments. Meanwhile, the portions of the first sidewall of the dielectric wall structure 126 not attached to the channel structures 108′-3 are exposed by the gate trench 166-3, and the portions of the second sidewall of the dielectric wall structure 126 not attached to the channel structures 108′-3 are exposed by the gate trench 166-4 in accordance with some embodiments.

Next, gate structures 168, 168-3, and 168-4 are formed in the gate trenches 166, 166-3, and 166-4, as shown in FIGS. 2M, 2M-1, and 2M-2 in accordance with some embodiments. In some embodiments, each of the gate structures 168, 168-3, and 168-4 includes a gate dielectric layer 170 and a gate electrode layer 172. Interfacial layers (not shown) may also be formed around the channel structures 108′-1, 108′-2, 108′-3, and 108′-4 and on the exposed portions of the base fin structures 104B and 104B-W. In some embodiments, the interfacial layers are oxide layers formed by performing a thermal process.

In some embodiments, the gate dielectric layers 170 are conformally formed over the gate trenches 166, 166-3, and 166-4. In some embodiments, the gate dielectric layers 170 wrap around the channel structures 108′-1, 108′-2, 108′-3, and 108′-4 and cover the sidewalls of the dielectric shell layer 118 and the top surface of the cap layer 124 of the dielectric wall structure 126 in accordance with some embodiments.

In some embodiments, the gate dielectric layers 170 are made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al2O₃) alloy, other applicable high-k dielectric materials, or a combination thereof. In some embodiments, the gate dielectric layers 170 are formed using CVD, ALD, other applicable methods, or a combination thereof.

In some embodiments, the gate electrode layers 172 are formed over the gate dielectric layers 170. In some embodiments, the gate electrode layers 172 are made of one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof. In some embodiments, the gate electrode layer 172 is formed using CVD, ALD, electroplating, another applicable method, or a combination thereof. Other conductive layers, such as work function metal layers, may also be formed in the gate structures 168, 168-3, and 168-4, although they are not shown in the figures.

In some embodiments, the gate structures 168 and 168-4 are first type of metal gate structures (e.g. the n-type) and the gate structure 168-3 is a second type of metal gate structure (e.g. the p-type) that is different from the first type of metal gate structure. In some embodiments, the interface between the gate structures 168-3 and 168-4 is located over the cap layer 124 of the dielectric wall structure 126.

The gate structures 168, 168-3, and 168-4 with different type of metal layers may be formed first and patterned afterwards. For example, p-type metal layers may first be formed in the gate trenches 166, 166-3, and 166-4, and then the portions of the p-type metal layers formed in the gate trenches 166 and 166-4 may be removed. Next, n-type metal layers may be formed in the gate trenches 166, 166-3, and 166-4, and the gate electrode layers may be formed over the n-type metal layers in the gate trenches 166, 166-3, and 166-4. Afterwards, a planarization process, such as CMP, may be performed until the interlayer dielectric layer 162 is exposed, thereby forming the gate structures 168, 168-3, and 168-4. In some other embodiments, the portion of the n-metal layer formed over the p-metal layer in the gate trench 166-3 is removed before the gate electrode layer is formed.

After the gate structures 168, 168-3, and 168-4 are formed, a hard mask layer 180 with openings 182 is formed over the gate structures 168, 168-3, and 168-4, and an etching process is performed through the openings 182 to form a trench 184 and a trench 186 through the gate structure 168 and through the interface of the gate structures 168-3 and 168-4, as shown in FIGS. 2N, 2N-1, and 2N-2 in accordance with some embodiments. The etching rate of the cap layer 124 during the etching process may be relatively low, compared to that of the gate structures, and therefore the bottom portion of the trench 186 stop inside the cap layer 124 without exposing the core portion 120 in accordance with some embodiments. Accordingly, the trench 184 is thicker than the trench 186 along the Z direction in accordance with some embodiments.

In some embodiments, the trench 184 is formed through the gate structure 168 to separate the gate structure 168 into two electrically isolated portions 168-1 and 168-2, as shown in FIG. 2N-1 in accordance with some embodiments. In addition, the trench 184 further extends into the isolation structure 116 in accordance with some embodiments. Meanwhile, the trench 186 is formed between the gate structures 168-3 and 168-4 and over the dielectric wall structure 126, so that the gate structures 168-3 and 168-4 are electrically isolated from each other by the dielectric wall structure 126 and the trench 186 in accordance with some embodiments. In addition, the cap layer 124 is also partially etched during the etching process, so that the trench 186 further extends into the cap layer 124 of the dielectric wall structure 126 in accordance with some embodiments.

In some embodiments, the portion of the cap layer 120 vertically under the trench 186 has a dimension D₁₀ along Z direction, and the dimension D₁₀ is in a range from about 5 nm to about 15 nm. In some embodiments, the thickness of the cap layer 124 in the channel region (D₁₀ shown in FIG. 2N-1) is greater than the thickness of the cap layer 124 in the source/drain region (D₉ shown in FIG. 2G). In some embodiments, the width of the trench 186 along the Y direction is smaller than the width of the cap layer 124 along the Y direction, and therefore the bottom portion of the trench 186 is laterally surrounded by the cap layer 124 in accordance with some embodiments.

After the trenches 184 and 186 are formed, isolation features 188 and 190 are formed in the trenches 184 and 186, as shown in FIGS. 2O. 2O-1, and 2O-2 in accordance with some embodiments. FIGS. 2O-3 illustrates an enlarged cross-sectional view of the semiconductor structure 100 in the block BK-O shown in FIG. 2O-1 in accordance with some embodiments.

The isolation feature 188 is configured to separate the gate structure 168 into electrically isolated portions 168-1 and 168-2, and the isolation feature 190 is configured to separate the gate structures 168-3 and 168-4 in accordance with some embodiments. In some embodiments, the isolation features 188 and 190 are formed after the gate structures 168, 168-3, and 168-4 are formed, so that the gate dielectric layer 170 does not cover the sidewalls of the isolation features 188 and 190.

In some embodiments, the isolation features 188 and 190 both include a barrier layer 192 and an isolation layer 194. In some embodiments, the barrier layer 192 is a nitride layer, and the isolation layer 194 is an oxide layer. In some embodiments, the isolation features 188 and 190 are formed by depositing the barrier layer 192 on the sidewalls and bottom surfaces of the trenches 184 and 186 and over the gate structures 168, 168-3, and 168-4, depositing the isolation layer 194 over the barrier layer, and polishing the isolation layer 194 and the barrier layer 192 until the top surface of the gate structures 168, 168-3, and 168-4 are exposed. The hard mask layer 180 may be removed during the polishing process or may be removed before forming the barrier layer 192. The barrier layer 192 and the isolation layer 194 may be formed by chemical vapor deposition (CVD), physical vapor deposition, (PVD), atomic layer deposition (ALD), or other applicable processes.

As shown in FIG. 2O-1, the semiconductor structure 100 includes the channel structures 108′-1 and 108′-2 vertically stacked over the base fin structures 104B in accordance with some embodiments. The isolation feature 188 is formed between and laterally spaced apart from the channel members 108′-1 and 108′-2 and is configured to separate the portions 168-1 and 168-2 of the gate structure 168 in accordance with some embodiments. In addition, the thickness of the isolation feature 188 along the Z direction is greater than the thickness of the gate structure 168, so that the isolation feature 188 further extends into the isolation structure 116 in accordance with some embodiments.

In addition, the semiconductor structure 100 further includes the channel structures 108′-3 and 108′-4 laterally spaced apart from each other but vertically overlapping the same base fin structure 104B-W, as shown in FIG. 2O-1 in accordance with some embodiments. The dielectric wall structure 126 is sandwiched between the channel structures 108′-3 and 108′-4 and is laterally attached to channel structures 108′-3 and 108′-4 in accordance with some embodiments. Furthermore, the dielectric wall structure 126 extends into and in direct contact with the base fin structure 104B-W in accordance with some embodiments.

The isolation feature 190 vertically overlaps the dielectric wall structure 126, so that the gate structures 168-3 and 168-4 are electrically isolated from each other by the dielectric wall structure 126 and the isolation feature 190 in accordance with some embodiments. In addition, the gate dielectric layer 170 covers the sidewalls of the dielectric wall structure 126 but does not cover the sidewall of the isolation feature 190 in accordance with some embodiments.

The dielectric wall structure 126 includes the dielectric shell layer 118 formed around the core portion 120 and the cap layer 124 in accordance with some embodiments. In some embodiments, the void 121 is embedded in the core portion 120 of the dielectric wall structure 126, and the k value of the dielectric wall structure 126 may therefore be relatively low in accordance with some embodiments. Furthermore, the cap layer 124 is formed at the upper portion of the dielectric wall structure 126, to prevent the isolation feature 190 from further extending into the lower portion of the structure. Accordingly, the risk of damaging the channel structures 108′-3 and 108′-4 during the formation of the isolation feature is highly reduced. In some embodiments, the bottom surface of the isolation feature 190 is higher than the topmost surface of the channel structures 108′-3 and 108′-4.

In some embodiments, the bottom surface of the isolation feature 190 is lower than the topmost surface of the cap layer 124 and the topmost surface of the dielectric shell layer 118. In some embodiments, the top surface of the isolation feature 190 is substantially level with the top surface of the isolation feature 188, but the bottom surface of the isolation feature 190 is higher than the bottom surface of the isolation feature 188. In some embodiments, the top surface of the cap layer 124 at the channel region is lower than the top surface of the cap layer 124 under the gate spacers 140, since the height of the cap layer 124 under the gate spacers 140 substantially remains its original height during the manufacturing processes.

Furthermore, the dielectric wall structure 126 further extends to the source/drain regions of the semiconductor structure 100, and the source/drain structures 150-3 and 150-4 are attached to opposite sidewalls of the dielectric wall structure 126, as shown in FIG. 2O in accordance with some embodiments. Therefore, the source/drain structures 150-3 and 150-4 can be separated by the dielectric wall structure 126. In addition, since the source/drain structures 150-3 and 150-4 are both confined by one fin spacer 142 at one side and the dielectric wall structure 126 at the other side, the shapes of the source/drain structures 150-3 and 150-4 are symmetrical to each other in the cross-sectional view along the Y direction in accordance with some embodiments. On the other hand, since the fin spacer 142 and the dielectric wall structure 126 have different height, the source/drain structures 150-3 and 150-4 by themselves are asymmetry in the cross-sectional view along the Y direction in accordance with some embodiments. In some embodiments, the vertical height of the dielectric wall structure 126 at the source/drain region is lower than the vertical height of the dielectric wall structure 126 at the channel region.

It should be appreciated that although FIGS. 2A-2 to 2O-2 illustrate the cross-sectional views of intermediate stages of manufacturing the fin structure 104-1 of the semiconductor structure 100, the cross-sectional views of the fin structures 104-2, 104-3, and 104-4 may be similar to, or the same as, those shown in FIGS. 2A-2 to 2O-2 and therefore are not repeated herein.

FIG. 3 illustrates a cross-sectional view of a semiconductor structure 100a in accordance with some embodiments. The semiconductor structure 100a may be similar to the semiconductor structure 100 described previously, except the isolation features are made of a single material in accordance with some embodiments. Processes and materials for forming the semiconductor structure 100a may be similar to, or the same as, those for forming the semiconductor structure 100 described previously and are not repeated herein.

More specifically, processes shown in FIGS. 2A to 2O, 2A-1 to 2O-1, and 2A-2 to 2O-2 may be performed, except the barrier layer 192 is not formed. That is, the isolation layer 194 is directly formed in the trenches (e.g. the trenches 184 and 186 shown in FIG. 2N-1) to form isolation features 188a and 190a, as shown in FIG. 3 in accordance with some embodiments. In some embodiments, the isolation layer 194 is made of a single oxide material or a nitride material.

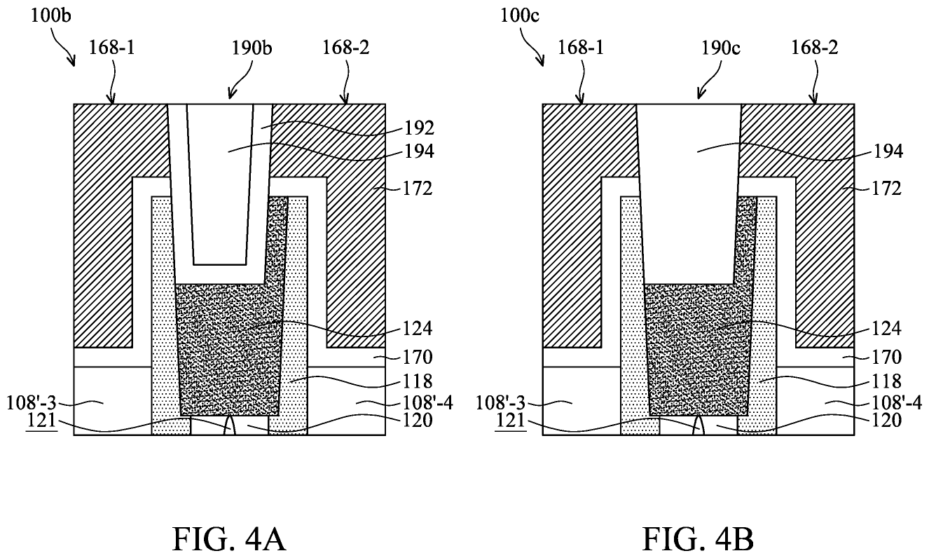

FIG. 4A illustrates an enlarged cross-sectional view of a semiconductor structure 100b in accordance with some embodiments. The semiconductor structure 100b may be similar to the semiconductor structure 100 described previously, except the position of the isolation feature is different from that in the semiconductor structure 100 in accordance with some embodiments. Processes and materials for forming the semiconductor structure 100b may be similar to, or the same as, those for forming the semiconductor structure 100 described previously and are not repeated herein. For example, the enlarged cross-sectional view shown in FIG. 4A may be similar to that shown in FISG. 2O-3, and other elements in the semiconductor structure 100b not shown in FIG. 4A may be similar to, or the same as, those shown in FIGS. 2O, 2O-1, and 2O-2 described previously in accordance with some embodiments.

More specifically, an isolation feature 190b of the semiconductor structure 100b is formed closer to the first sidewall than to the second sidewall of the dielectric wall structure 126 in accordance with some embodiments. In some embodiments, a first sidewall of the isolation feature 190b is in direct contact with the dielectric shell layer 118, while a second sidewall of the isolation feature 190b is spaced apart from the dielectric shell layer 118. That is, a portion of the cap layer 124 is sandwiched between the second sidewall of the isolation feature 190b and the dielectric shell layer 118 in accordance with some embodiments.

FIG. 4B illustrates an enlarged cross-sectional view of a semiconductor structure 100c in accordance with some embodiments. The semiconductor structure 100c may be similar to the semiconductor structure 100b described previously, except the isolation feature is made of a single material in accordance with some embodiments. Processes and materials for forming the semiconductor structure 100c may be similar to, or the same as, those for forming the semiconductor structures 100, 100a, and 100b described previously and are not repeated herein. For example, the enlarged cross-sectional view shown in FIG. 4B may be similar to that shown in FIGS. 2O-3, and other elements in the semiconductor structure 100c not shown in FIG. 4B may be similar to, or the same as, those shown in FIGS. 2O, 2O-1, and 2O-2 described previously in accordance with some embodiments.

More specifically, a first sidewall of the isolation layer 194 of the isolation feature 190c is in direct contact with the dielectric shell layer 118, while a second sidewall of the isolation layer 194 of the isolation feature 190c is spaced apart from the dielectric shell layer 118. That is, a portion of the cap layer 124 is sandwiched between the second sidewall of the isolation layer 194 of the isolation feature 190c and the dielectric shell layer 118 in accordance with some embodiments.

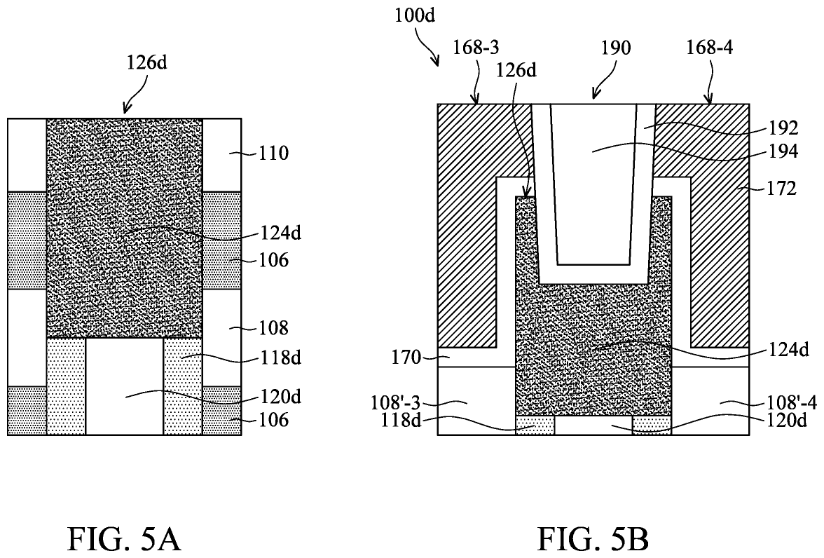

FIGS. 5A and 5B illustrate enlarged cross-sectional views of intermediate stages of manufacturing a semiconductor structure 100d in accordance with some embodiments. The semiconductor structure 100d may be similar to the semiconductor structure 100 described previously, except structure of the dielectric wall structure is different from that of the semiconductor structure 100 in accordance with some embodiments. Processes and materials for forming the semiconductor structure 100d may be similar to, or the same as, those for forming the semiconductor structure 100 described previously and are not repeated herein. For example, the enlarged cross-sectional view shown in FIG. 5B may be similar to that shown in FIGS. 2O-3, and other elements in the semiconductor structure 100d not shown in FIG. 5B may be similar to, or the same as, those shown in FIGS. 2O, 2O-1, and 2O-2 described previously in accordance with some embodiments.

More specifically, the processes shown in FIGS. 2A to 2D, 2A-1 to 2D-1, and 2A-2 to 2D-2 are performed, and a dielectric shell layer 118d and a core portion 120d are recessed, and a cap layer 124d is formed over the dielectric shell layer 118d and the core portion 120d to form a dielectric wall structure 126d, as shown in FIG. 5A in accordance with some embodiments. In addition, the dielectric shell layer 118d and the core portion 120d at the upper portion are fully recessed, so that the cap layer 124d directly covered the sidewalls of the fin structures 104-3 and 104-4 in accordance with some embodiments.

Afterwards, the processes shown in FIGS. 2F to 2O, 2F-1 to 2O-1, and 2F-2 to 2O-2 are performed to form the semiconductor structure 100d, as shown in FIG. 5B in accordance with some embodiments. Since the dielectric shell layer 118d is fully recessed before forming the cap layer 124d, no dielectric shell layer 118d is laterally sandwiched between the isolation feature 190 and the gate structures 168-3 and 168-4 in accordance with some embodiments. The processes and materials for forming the dielectric shell layer 118d, the core portion 120d, and the cap layer 124d are similar to, or the same as, those for forming the dielectric shell layer 118, the core portion 120, and the cap layer 124 described previously and are not repeated herein.

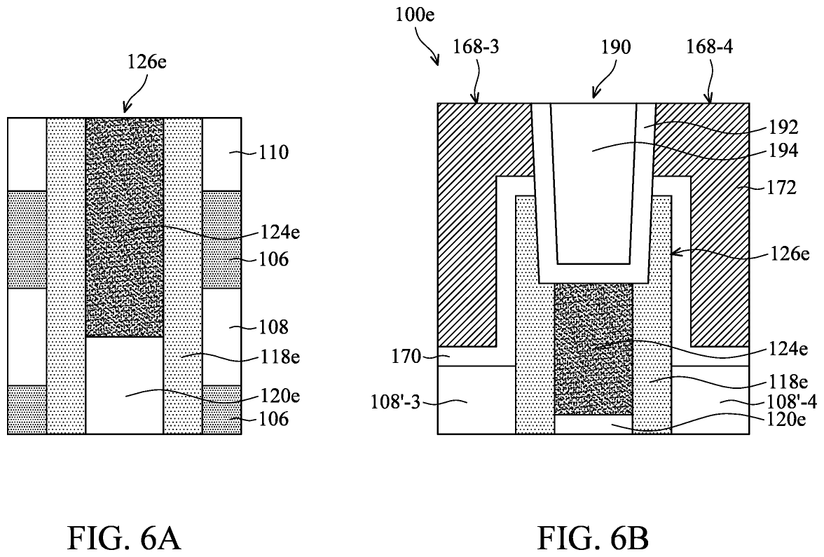

FIGS. 6A and 6B illustrate enlarged cross-sectional views of intermediate stages of manufacturing a semiconductor structure 100e in accordance with some embodiments. The semiconductor structure 100e may be similar to the semiconductor structure 100 described previously, except structure of the dielectric wall structure is different from that of the semiconductor structure 100 in accordance with some embodiments. Processes and materials for forming the semiconductor structure 100e may be similar to, or the same as, those for forming the semiconductor structure 100 described previously and are not repeated herein. For example, the enlarged cross-sectional view shown in FIG. 6B may be similar to that shown in FIGS. 2O-3, and other elements in the semiconductor structure 100e not shown in FIG. 6B may be similar to, or the same as, those shown in FIGS. 2O, 2O-1, and 2O-2 described previously in accordance with some embodiments.

More specifically, the processes shown in FIGS. 2A to 2D, 2A-1 to 2D-1, and 2A-2 to 2D-2 are performed, and a core portion 120e is recessed without recessing a dielectric shell layer 118e, and a cap layer 124e is formed over the core portion 120e to form a dielectric wall structure 126e, as shown in FIG. 6A in accordance with some embodiments. In some embodiments, the sidewall of the cap layer 124e is substantially aligned with the sidewall of the core portion 120e.

Afterwards, the processes shown in FIGS. 2F to 2O, 2F-1 to 2O-1, and 2F-2 to 2O-2 are performed to form the semiconductor structure 100e, as shown in FIG. 6B in accordance with some embodiments. Since the dielectric shell layer 118e is not recessed, a portion of the dielectric shell layer 118e laterally surrounds and is in direct contact with the bottom portion of the isolation feature 190 in accordance with some embodiments. The processes and materials for forming the dielectric shell layer 118e, the core portion 120e, and the cap layer 124e are similar to, or the same as, those for forming the dielectric shell layer 118, the core portion 120, and the cap layer 124 described previously and are not repeated herein.

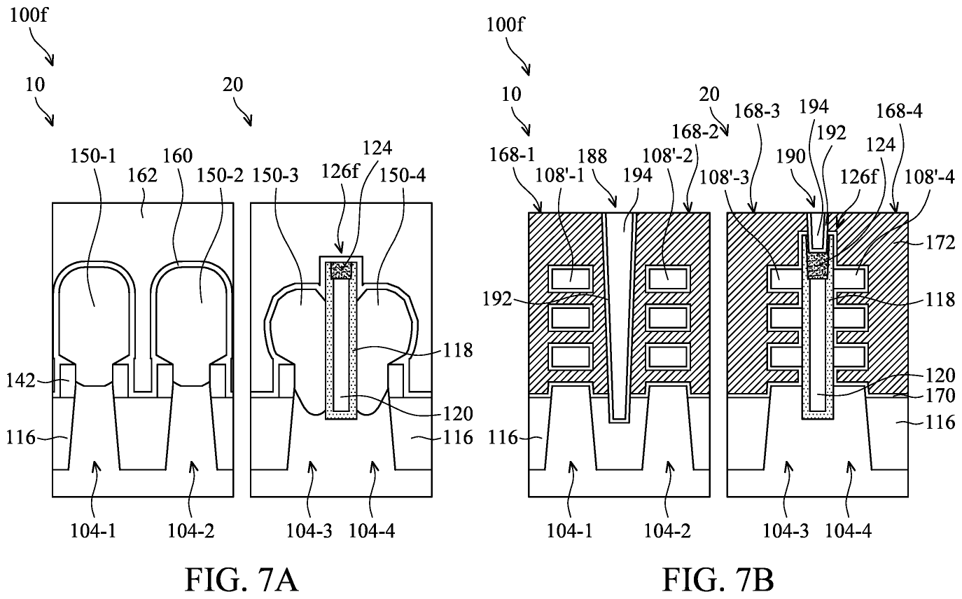

FIGS. 7A and 7B illustrate cross-sectional views of a semiconductor structure 100f in accordance with some embodiments. The semiconductor structure 100f may be similar to the semiconductor structure 100 described previously, except no void is formed in the dielectric wall structure in accordance with some embodiments. More specifically, a dielectric wall structure 126f is formed, and no void is formed in the core portion 120 of the dielectric wall structure 126f in accordance with some embodiments. Processes and materials for forming the semiconductor structure 100f may be similar to, or the same as, those for forming the semiconductor structure 100 described previously and are not repeated herein.

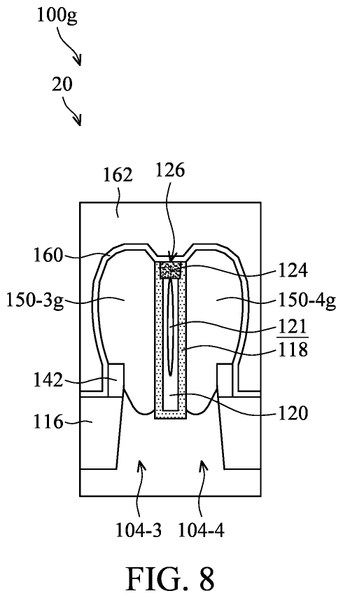

FIG. 8 illustrates a cross-sectional view of a semiconductor structure 100g in accordance with some embodiments. The semiconductor structure 100g may be similar to the semiconductor structure 100 described previously, except the source/drain structures are relatively high in accordance with some embodiments. More specifically, source/drain structures 150-3g and 150-4g are formed at opposite sides of the dielectric wall structure 126 in accordance with some embodiments. In addition, the topmost portion of the source/drain structure 150-3g and the topmost portion of the source/drain structure 150-4g are higher than the top surface of the dielectric wall structure 126 in accordance with some embodiments. Although the source/drain structures 150-3g and 150-4g are higher than the dielectric wall structure 126, they can still be separated by the dielectric wall structure 126.

Processes and materials for forming the semiconductor structure 100g may be similar to, or the same as, those for forming the semiconductor structure 100 described previously and are not repeated herein. In addition, the processes and materials for forming the source/drain structures 150-3g and 150-4g are similar to, or the same as, those for forming the source/drain structures 150-3 and 150-4 described previously and are not repeated herein.

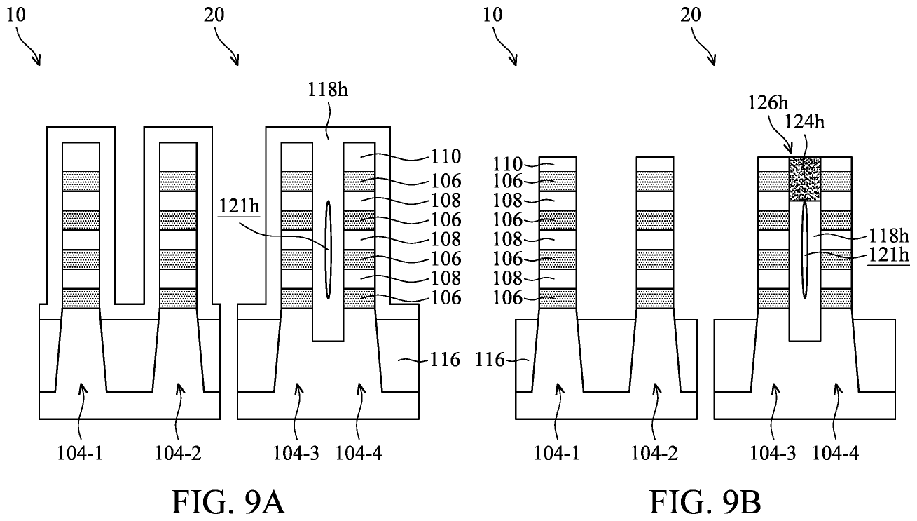

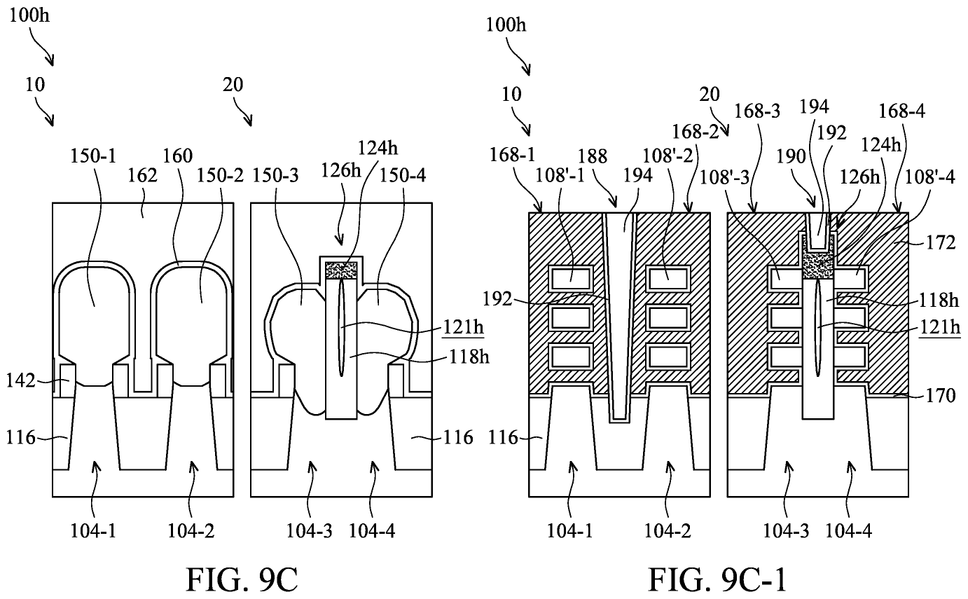

FIGS. 9A to 9C illustrate cross-sectional views of intermediate stages of manufacturing a semiconductor structure 100h in accordance with some embodiments. The semiconductor structure 100h may be similar to the semiconductor structure 100 described previously, except the dielectric wall structure is different from that of the semiconductor structure 100 in accordance with some embodiments. Processes and materials for forming the semiconductor structure 100h may be similar to, or the same as, those for forming the semiconductor structure 100 described previously and are not repeated herein.

More specifically, the processes shown in FIGS. 2A to 2B, 2A-1 to 2B-1, and 2A-2 to 2B-2 are performed, and a dielectric shell layer 118h is formed without forming the core portion, as shown in FIG. 9A in accordance with some embodiments. In addition, a void 121h is formed in the dielectric shell layer 118h in accordance with some embodiments. Afterwards, the processes shown in FIGS. 2D to 2E, 2D-1 to 2E-1, and 2D-2 to 2E-2 are performed to form a dielectric wall structure 126h, as shown in FIG. 9B in accordance with some embodiments. Next, the processes shown in FIGS. 2F to 2O, 2F-1 to 2O-1, and 2F-2 to 2O-2 are performed to form the semiconductor structure 100h, as shown in FIG. 9C in accordance with some embodiments. FIG. 9C-1 illustrates a cross-sectional view of the semiconductor structure 100h in the channel region in accordance with some embodiments. The processes and materials for forming the dielectric shell layer 118h and the cap layer 124h are similar to, or the same as, those for forming the dielectric shell layer 118 and the cap layer 124 described previously and are not repeated herein.

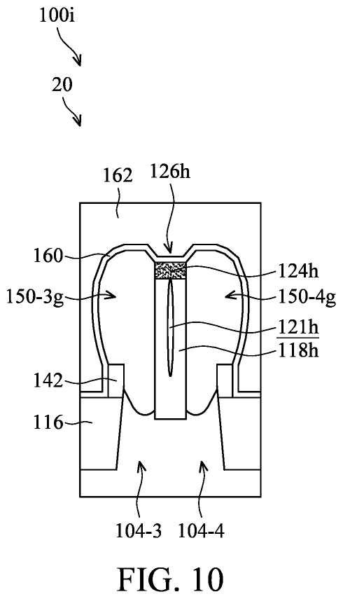

FIG. 10 illustrates a cross-sectional view of a semiconductor structure 100i in accordance with some embodiments. The semiconductor structure 100i may be similar to the semiconductor structure 100h described previously, except the source/drain structures are relatively high in accordance with some embodiments. More specifically, the source/drain structures 150-3g and 150-4g are formed at opposite sides of the dielectric wall structure 126h in accordance with some embodiments. In addition, the topmost portion of the source/drain structure 150-3g and the topmost portion of the source/drain structure 150-4g are higher than the top surface of the dielectric wall structure 126h in accordance with some embodiments.

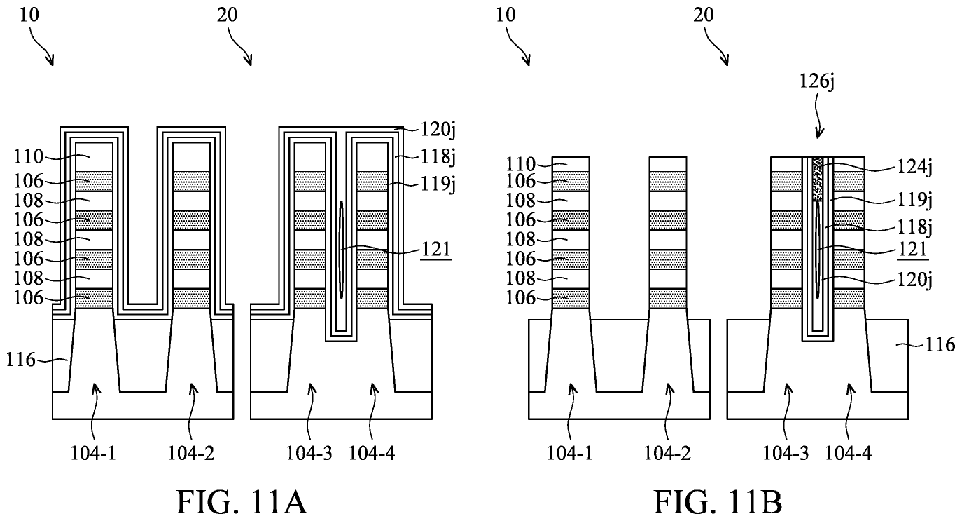

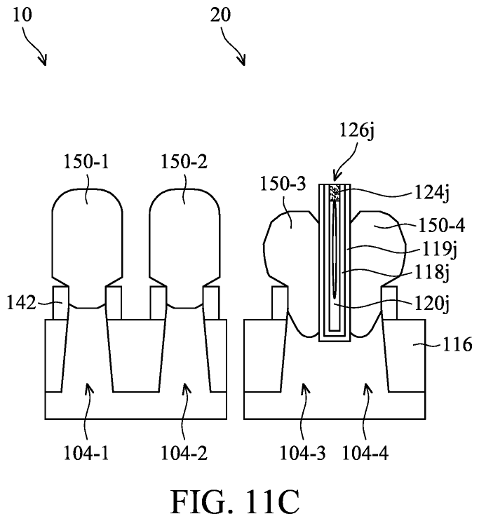

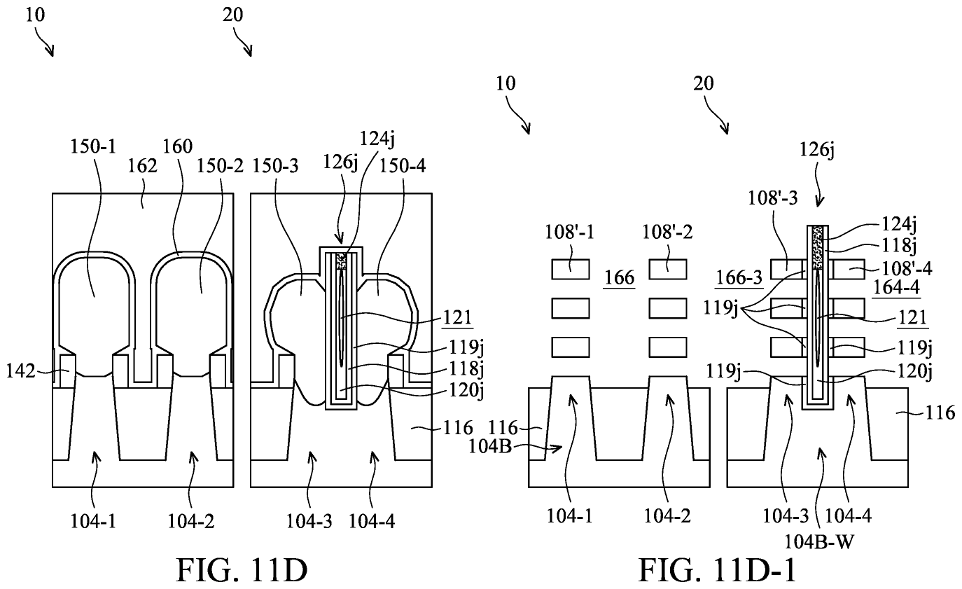

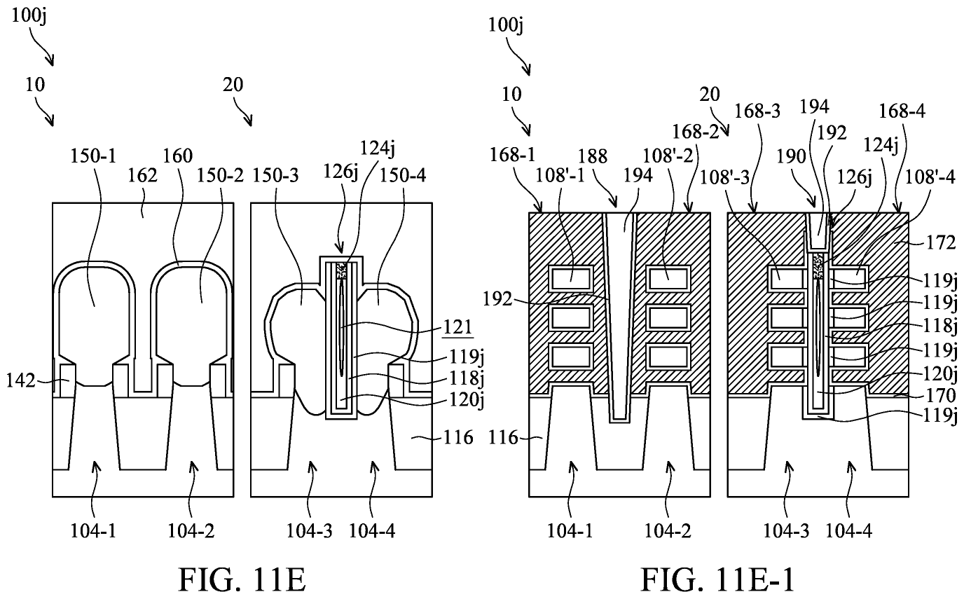

FIGS. 11A to 11E illustrate cross-sectional views of intermediate stages of manufacturing a semiconductor structure 100j in accordance with some embodiments. The semiconductor structure 100j may be similar to the semiconductor structure 100 described previously, except structure of the dielectric wall structure is different from that of the semiconductor structure 100 in accordance with some embodiments. Processes and materials for forming the semiconductor structure 100j may be similar to, or the same as, those for forming the semiconductor structure 100 described previously and are not repeated herein.

More specifically, the processes shown in FIGS. 2A to 2B, 2A-1 to 2B-1, and 2A-2 to 2B-2 are performed, and a liner layer 191j is formed before a dielectric shell layer 118j and a core portion 120i are formed, as shown in FIG. 11A in accordance with some embodiments. In some embodiments, the liner layer 191j is an oxide layer. In some embodiments, the liner layer 191j is thinner than the dielectric shell layer 118j. In some embodiments, the liner layer 191j has a thickness in a range from about 1 nm to about 3 nm.

Afterwards, the processes shown in FIGS. 2D to 2E, 2D-1 to 2E-1, and 2D-2 to 2E-2 are performed to form a dielectric wall structure 126j, as shown in FIG. 11B in accordance with some embodiments. In some embodiments, the cap layer 124j is laterally surrounded by the dielectric shell layer 118j and the liner layer 119j. Next, the processes shown in FIGS. 2F to 2J, 2F-1 to 2J-1, and 2F-2 to 2J-2 are performed to form the source/drain structures 150-1, 150-2, 150-3, and 150-4, as shown in FIG. 11C in accordance with some embodiments. In some embodiments, the source/drain structures 150-3 and 150-4 are in direct contact with the liner layer 119j of the dielectric wall structure 126j.

After the source/drain structures 150-1, 150-2, 150-3, and 150-4 are formed, the processes shown in FIGS. 2K to 2L, 2K-1 to 2L-1, and 2K-2 to 2L-2 are performed to remove the dummy gate structures 130 and the first semiconductor material layers 106, so that the gate trenches 166, 166-3, and 166-4 are formed, as shown in FIGS. 11D and 11D-1 in accordance with some embodiments. FIG. 11D-1 illustrates a cross-sectional view of the intermediate stage of the semiconductor structure 100j in the channel region in accordance with some embodiments. As shown in FIG. 11D-1, the liner layer 119j formed on the sidewalls of the first semiconductor material layers 106 are also removed in accordance with some embodiments. Accordingly, the liner layer 119j in the channel region becomes dis-continuously and only partially covered the sidewall of the dielectric shell layer 118j in accordance with some embodiments. In addition, a portion of the liner layer 119j is sandwiched between the bottom portion of the dielectric shell layer 118j and the base fin structure 104B-W and in direct contact with the base fin structure 104B-W in accordance with some embodiments.

Afterwards, the processes shown in FIGS. 2M to 2O, 2M-1 to 2O-1, and 2M-2 to 2O-2 are performed to form the semiconductor structure 100j, as shown in FIGS. 11E and 11E-1 in accordance with some embodiments. FIG. 11E-1 illustrates a cross-sectional view of the semiconductor structure 100j in the channel region in accordance with some embodiments. In some embodiments, the gate structures 168-3 and 168-4 are in direct contact with both the liner layer 119j and the dielectric shell layer 118j.

The processes and materials for forming the dielectric shell layer 118j, the core portion 120j, and the cap layer 124j are similar to, or the same as, those for forming the dielectric shell layer 118, the core portion 120, and the cap layer 124 described previously and are not repeated herein.

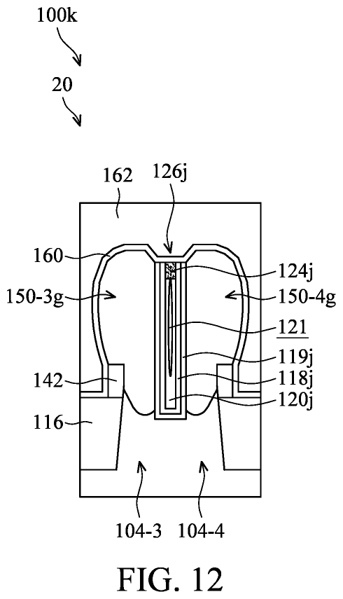

FIG. 12 illustrates a cross-sectional view of a semiconductor structure 100k in accordance with some embodiments. The semiconductor structure 100k may be similar to the semiconductor structure 100j described previously, except the source/drain structures are relatively high in accordance with some embodiments. More specifically, the source/drain structures 150-3g and 150-4g are formed at opposite sides of the dielectric wall structure 126j in accordance with some embodiments. In addition, the topmost portion of the source/drain structure 150-3g and the topmost portion of the source/drain structure 150-4g are higher than the top surface of the dielectric wall structure 126j in accordance with some embodiments.

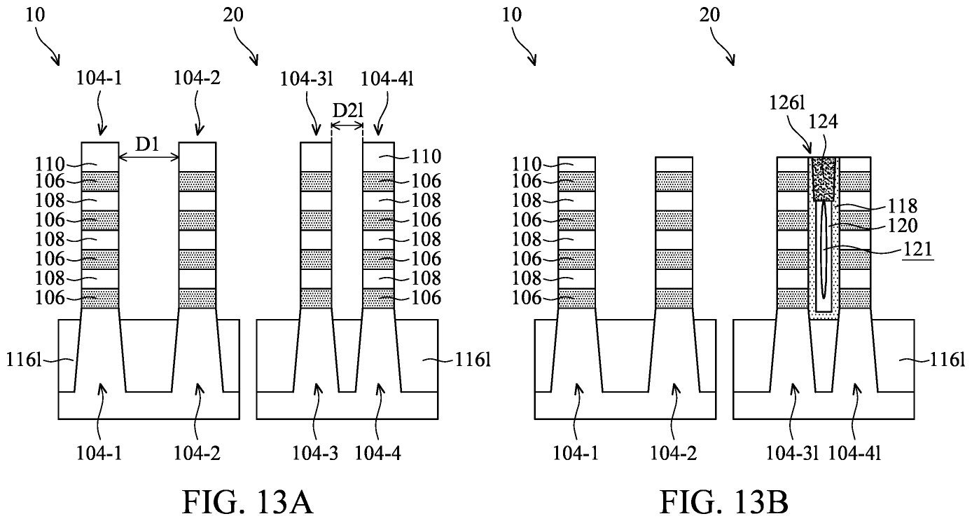

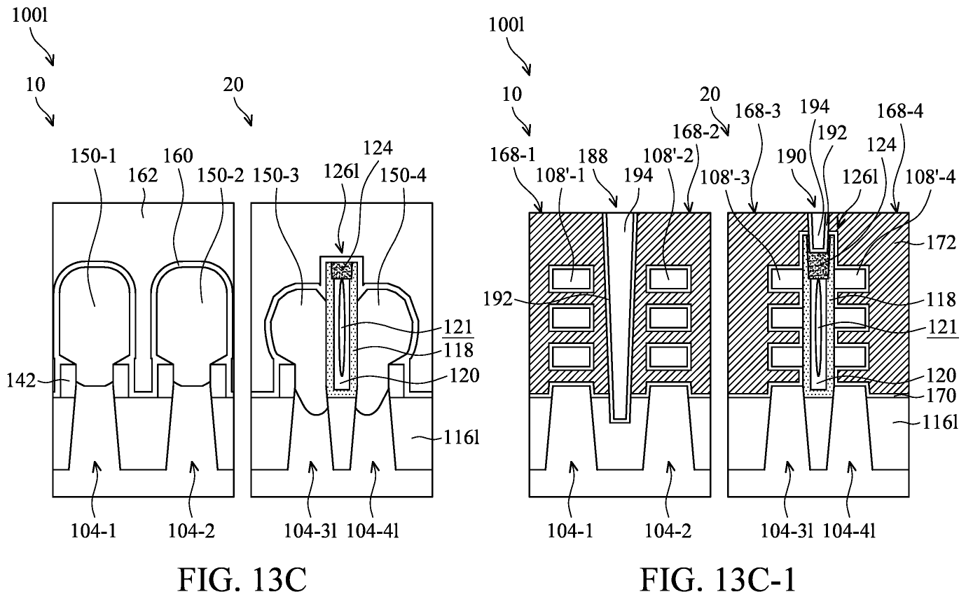

FIGS. 13A to 13C illustrate cross-sectional views of intermediate stages of manufacturing a semiconductor structure 100l in accordance with some embodiments. The semiconductor structure 100l may be similar to the semiconductor structure 100 described previously, except the fin structures with different pitches are patterned first in accordance with some embodiments. Processes and materials for forming the semiconductor structure 100l may be similar to, or the same as, those for forming the semiconductor structure 100 described previously and are not repeated herein.

More specifically, the semiconductor stack is patterned to form fin structures 104-1, 104-2, 104-3l, and 104-4l, and an isolation structure 116l is formed around the fin structures 104-1, 104-2, 104-3l, and 104-4l afterward, as shown in FIG. 13A in accordance with some embodiments. The distance D₂₁ between the fin structures 104-3l and 104-4l may be substantially the same with the distance D₂ between the fin structures 104-3 and 104-4 shown in FIG. 2B in accordance with some embodiments. Since the isolation structure 116l is formed after the fin structures 104-3l and 104-4l are patterned, the isolation structure 116l is formed in the space between the fin structures 104-3l and 104-4l in accordance with some embodiments.

Afterwards, the processes shown in FIGS. 2C to 2E, 2C-1 to 2E-1, and 2C-2 to 2E-2 are performed to form a dielectric wall structure 1261, as shown in FIG. 13B in accordance with some embodiments. As shown in FIG. 13B, the dielectric wall structure 1261 is formed over the isolation structure 116l in accordance with some embodiments. That is, the bottom surface of the dielectric wall structure 1261 is substantially level with the top surface of the isolation structure 116l in accordance with some embodiments.

Afterwards, the processes shown in FIGS. 2F to 2O, 2F-1 to 2O-1, and 2F-2 to 2O-2 are performed to form the semiconductor structure 1001, as shown in FIGS. 13C and 13C-1 in accordance with some embodiments. FIG. 13C-1 illustrates a cross-sectional view of the semiconductor structure 100l in the channel region in accordance with some embodiments. In some embodiments, the bottom surface of the dielectric wall structure 1261 is substantially level with the bottom surface of the gate structures 168-3 and 168-4 as shown in FIG. 13-1. In some embodiments, the bottom surface of the dielectric wall structure 1261 is higher than the bottom portions of the source/drain structures 150-3 and 150-4. In some embodiments, the bottom portions of the source/drain structures 150-3 and 150-4 are separated by the isolation structure 116l , as shown in FIG. 13C. The processes and materials for forming the isolation structure 116l is similar to, or the same as, those for forming the isolation structure 116 described previously and are not repeated herein.

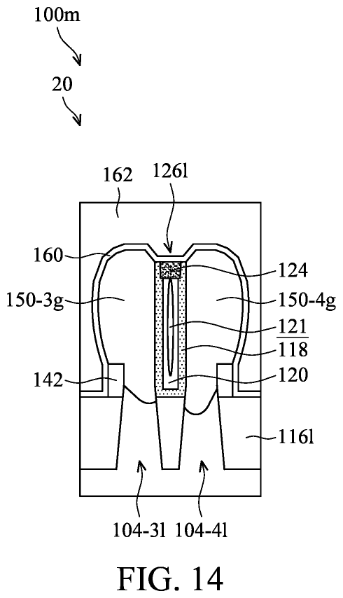

FIG. 14 illustrates a cross-sectional view of a semiconductor structure 100m in accordance with some embodiments. The semiconductor structure 100m may be similar to the semiconductor structure 100l described previously, except the source/drain structures are relatively high in accordance with some embodiments. More specifically, the source/drain structures 150-3g and 150-4g are formed at opposite sides of the dielectric wall structure 1261 in accordance with some embodiments. In addition, the topmost portion of the source/drain structure 150-3g and the topmost portion of the source/drain structure 150-4g are higher than the top surface of the dielectric wall structure 1261, and the bottom portion of the of the source/drain structure 150-3g and the bottom portion of the source/drain structure 150-4g are lower than the bottom surface of the dielectric wall structure 1261 in accordance with some embodiments.

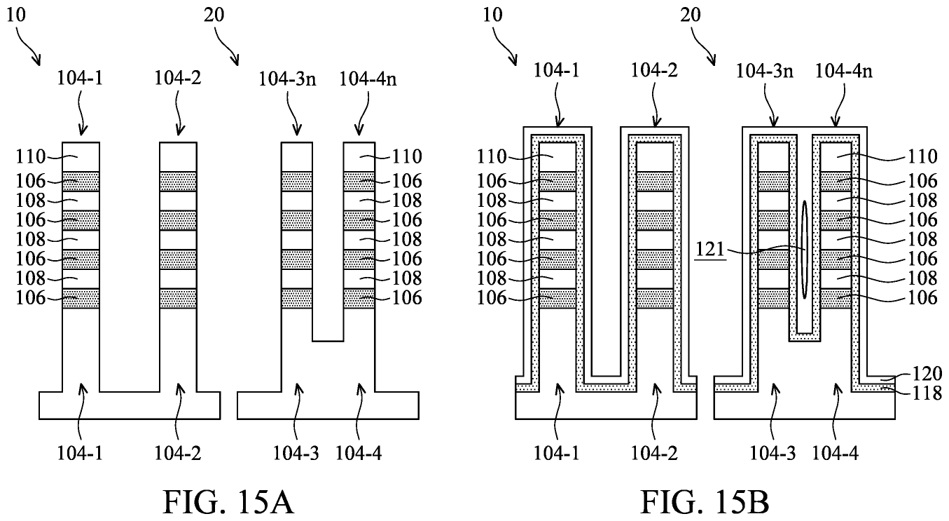

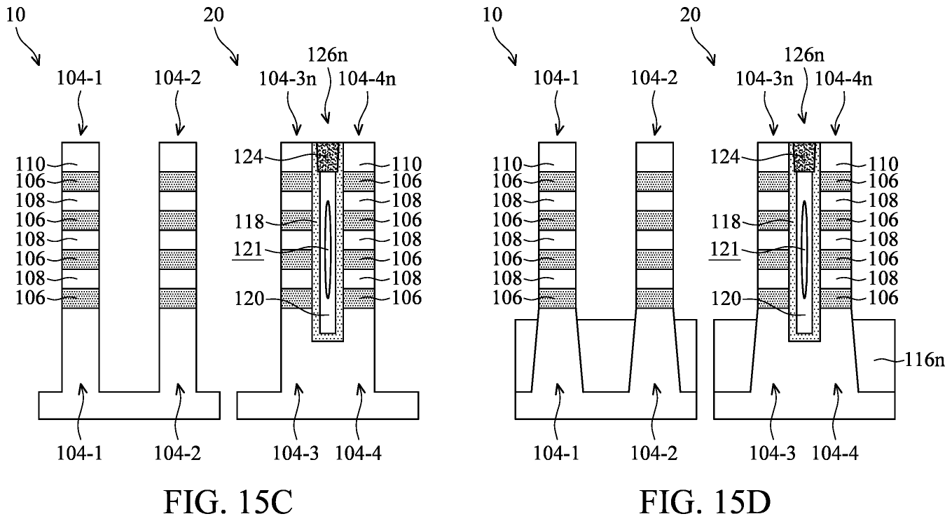

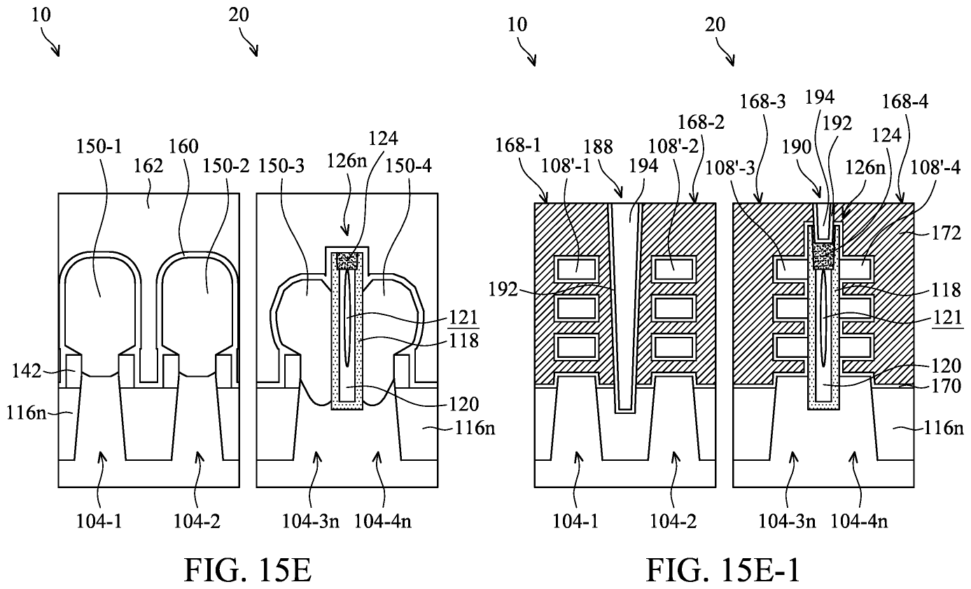

FIGS. 15A to 15E illustrate cross-sectional views of intermediate stages of manufacturing a semiconductor structure 100n in accordance with some embodiments. The semiconductor structure 100n may be similar to the semiconductor structure 100 described previously, except the dielectric wall structure is formed before the isolation structure is formed in accordance with some embodiments. Processes and materials for forming the semiconductor structure 100n may be similar to, or the same as, those for forming the semiconductor structure 100 described previously and are not repeated herein.

More specifically, the processes shown in FIGS. 1A, 1i, and 2B are performed to form fin structures 104-1, 104-2, 104-3n, and 104-4n without forming the isolation structure, as shown in FIG. 15A in accordance with some embodiments. Afterwards, the dielectric shell layer 118 and the core portion 120 are conformally formed over the fin structures 104-1, 104-2, 104-3n, and 104-4n, as shown in FIG. 15B in accordance with some embodiments. Next, the processes shown in FIGS. 2D to 2E, 2D-1 to 2E-1, and 2D-2 to 2E-2 are performed to form a dielectric wall structure 126n, as shown in FIG. 15C in accordance with some embodiments. After the dielectric wall structure 126n is formed, an isolation structure 116n is then formed around the fin structures 104-1, 104-2, 104-3n, and 104-4n, as shown in FIG. 15D in accordance with some embodiments.

Afterwards, the processes shown in FIGS. 2F to 2O, 2F-1 to 2O-1, and 2F-2 to 2O-2 are performed to form the semiconductor structure 100n, as shown in FIGS. 15E and 15E-1 in accordance with some embodiments. FIG. 15E-1 illustrates a cross-sectional view of the semiconductor structure 100n in the channel region in accordance with some embodiments. The processes and materials for forming the fin structures 104-3n, 104-4n, and the isolation structure 116n are similar to, or the same as, those for forming the fin structures 104-3, 104-4, and the isolation structure 116 described previously and are not repeated herein.

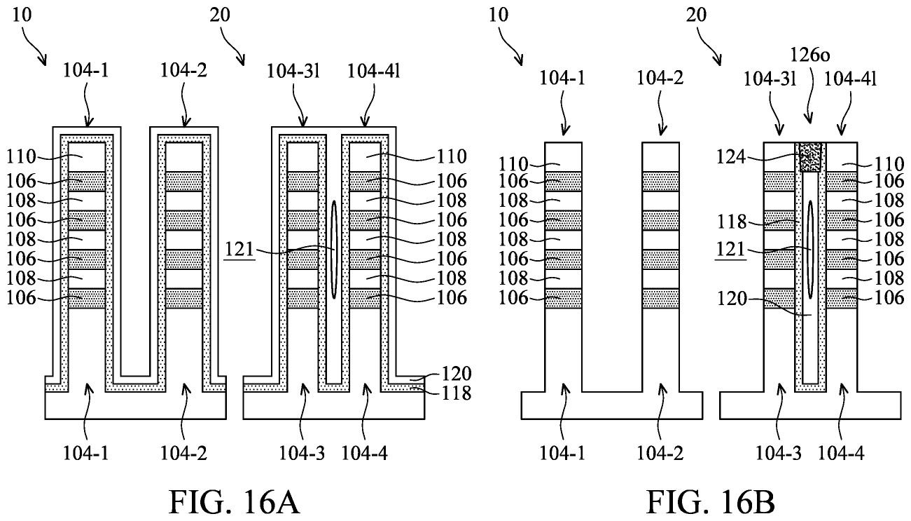

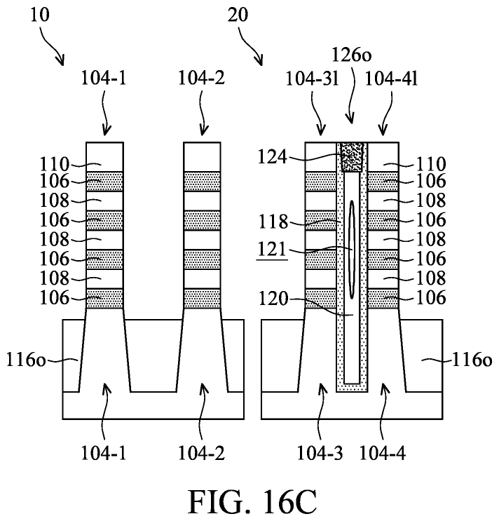

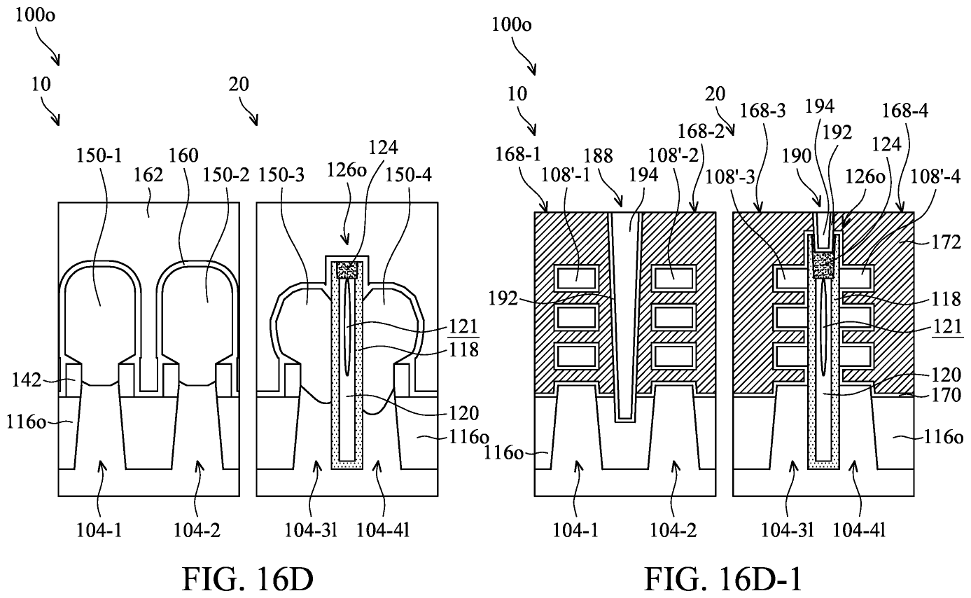

FIGS. 16A to 16D illustrate cross-sectional views of intermediate stages of manufacturing a semiconductor structure 100o in accordance with some embodiments. The semiconductor structure 100o may be similar to the semiconductor structure 1001 described previously, except the dielectric wall structure is formed before the isolation structure is formed in accordance with some embodiments. Processes and materials for forming the semiconductor structure 100o may be similar to, or the same as, those for forming the semiconductor structure 100l described previously and are not repeated herein.

More specifically, the fin structures 104-1, 104-2, 104-3l, and 104-4l are formed, and the dielectric shell layer 118 and the core portion 120 are conformally formed over the fin structures 104-1, 104-2, 104-3l, and 104-4l without forming the isolation structure first, as shown in FIG. 16A in accordance with some embodiments. Next, the processes shown in FIGS. 2D to 2E, 2D-1 to 2E-1, and 2D-2 to 2E-2 are performed to form a dielectric wall structure 126o, as shown in FIG. 16B in accordance with some embodiments. After the dielectric wall structure 126o is formed, an isolation structure 116o is formed around the fin structures 104-1, 104-2, 104-3l, and 104-4l, as shown in FIG. 16C in accordance with some embodiments. In some embodiments, the bottom surface of the dielectric wall structure 126o is substantially level with the bottom surface of the isolation structure 116o.

Afterwards, the processes shown in FIGS. 2F to 2O, 2F-1 to 2O-1, and 2F-2 to 2O-2 are performed to form the semiconductor structure 100o, as shown in FIGS. 16D and 16D-1 in accordance with some embodiments. FIG. 16D-1 illustrates a cross-sectional view of the semiconductor structure 100o in the channel region in accordance with some embodiments. The processes and materials for forming the isolation structure 116o is similar to, or the same as, those for forming the isolation structure 116 described previously and are not repeated herein.

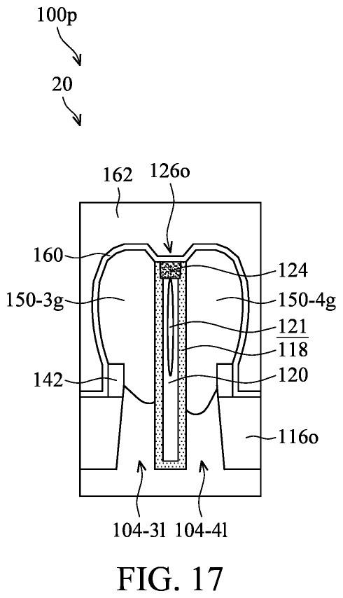

FIG. 17 illustrates a cross-sectional view of a semiconductor structure 100p in accordance with some embodiments. The semiconductor structure 100p may be similar to the semiconductor structure 100o described previously, except the source/drain structures are relatively high in accordance with some embodiments. More specifically, the source/drain structures 150-3g and 150-4g are formed at opposite sides of the dielectric wall structure 126o in accordance with some embodiments. In addition, the topmost portion of the source/drain structure 150-3g and the topmost portion of the source/drain structure 150-4g are higher than the top surface of the dielectric wall structure 126o, and the bottom portion of the of the source/drain structure 150-3g and the bottom portion of the source/drain structure 150-4g are higher than the bottom surface of the dielectric wall structure 126o in accordance with some embodiments.

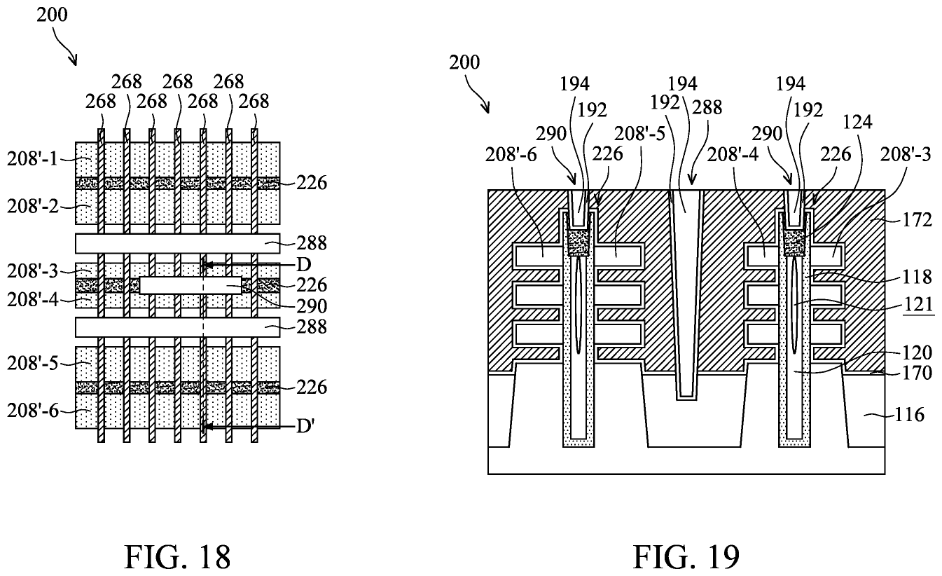

It should be appreciated that the elements shown in the semiconductor structures 100 and 100a to 100p may be combined and/or exchanged. For example, a semiconductor structure may include more than one dielectric wall structures described above. FIG. 18 illustrates a diagrammatic top view of a semiconductor structure 200 in accordance with some embodiments. The semiconductor structure 200 includes channel structures 208′-1, 208′-2, 208′-3, 208′-4, 208′-5, 208′-6, 208′-7, and 208′-8 longitudinally oriented along the X direction in accordance with some embodiments. The channel structures 208′-1, 208′-2, 208′-3, 208′-4, 208′-5, 208′-6, 208′-7, and 208′-8 may be similar to, or the same as, the channel structures 108′-1, 108′-2, 108′-3, and 108′-4 described previously. The channel structures 208′-1, 208′-2, 208′-3, 208′-4, 208′-5, 208′-6, 208′-7, and 208′-8 may have different conductive types. For examples, the channel structures 208′-1, 208′-4, and 208′-5 may be p-type channel structures, and the channel structures 208′-2, 208′-3, and 208′-6 may be n-type channel structures.

In addition, the semiconductor structure 200 further includes gate structures 268 longitudinally oriented along the Y direction and wrapping around the channel structures 208′-1, 208′-2, 208′-3, 208′-4, 208′-5, 208′-6, 208′-7, and 208′-8 in accordance with some embodiments. The gate structures 268 may be similar to, or the same as, the gate structures 168, 168-1, 168-2, 168-3, and 168-4 described previously. For example, the gate structures 268 may include n-metal layer, p-metal layers, or a combination thereof.

The semiconductor structure 200 further includes dielectric wall structures 226 longitudinally oriented along the X direction and being sandwiched between the channel structures 208′-1 and 208′-2, between the channel structures 208′-3 and 208′-4, and between the channel structures 208′-5 and 208′-6 in accordance with some embodiments. The dielectric wall structures 226 may be similar to, or the same as, the dielectric wall structures 126, 126d, 126e, 126f, 126h, 126j, 1261, 126n, and 126o described previously. In some embodiments, the portions of the gate structures 268 at opposite sides of the dielectric wall structures 226 are different types of metal gate structures.

The semiconductor structure 200 further includes isolation features 288 and 290 longitudinally oriented along the X direction, as shown in FIG. 18 in accordance with some embodiments. The isolation features 288 and 290 are configured to isolate different portions of the gate structures 268. The isolation features 288 may be similar to, or the same as, the isolation features 188 and 188a described previously. Similarly, the isolation feature 290 may be similar to, or the same as, the isolation features 190, 190a, 190b, and 190b described previously.

FIG. 19 illustrates one of the possible examples of the cross-sectional view of the semiconductor structure 200 shown along line D-D′ of FIG. 18 in accordance with some embodiments. More specifically, the channel structures 208′-3 and 208′-4 are attached to opposite sides of one of the dielectric wall structures 226, and the channel structures 208′-5 and 208′-6 are attached to opposite sides of one of the dielectric wall structures 226 in accordance with some embodiments. The dielectric wall structures 226 may be similar to, or the same as, the dielectric wall structure 126o shown in FIG. 16D-1. In addition, the channel structures 208′-3, 208′-4, 208′-5, and 208′-6 may be similar to, or the same as, the channel structures 108′-3 and 108′-4 described previously. In some embodiments, the channel structures 208′-5 and 208′-6 are wider than the channel structures 208′-3 and 208′-4.

The isolation features 288 and 290 may be similar to, or the same as, the isolation features 188 and 190 described previously. In some embodiments, the isolation feature 288 is spaced apart from the isolation features 290, and the isolation feature 288 and the isolation features 290 are in physical contact with opposite sidewalls of a portion of the gate structure 268. In addition, the isolation feature 288 is thicker than the isolation features 290 along the Z direction in accordance with some embodiments.

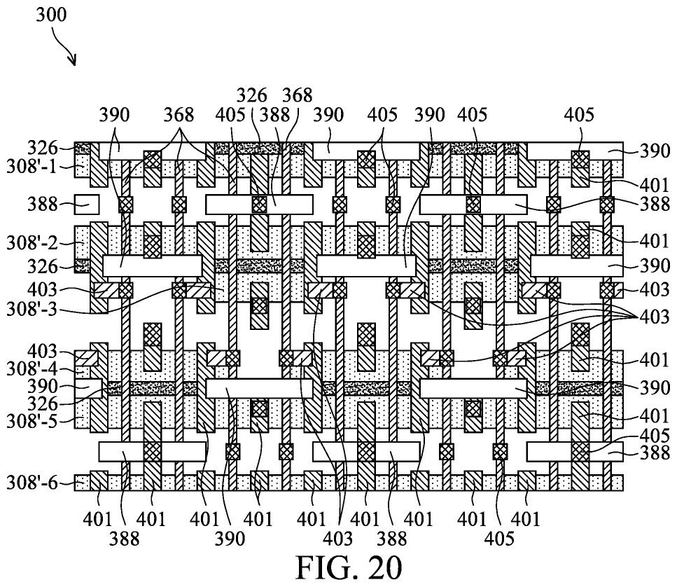

FIG. 20 illustrates a diagrammatic top view of a semiconductor structure 300 in accordance with some embodiments. The semiconductor structure 300 includes channel structures 308′-1, 308′-2, 308′-3, 308′-4, 308′-5, and 308′-6 longitudinally oriented along the X direction in accordance with some embodiments. The channel structures 308′-1, 308′-2, 308′-3, 308′-4, 308′-5, and 308′-6 may be similar to, or the same as, the channel structures 108′-1, 108′-2, 108′-3, and 108′-4 described previously. The channel structures 308′-1, 308′-2, 308′-3, 308′-4, 308′-5, and 308′-6 may have different conductive types. For examples, the channel structures 308′-3 and 308′-4 may be p-type channel structures, whereas channel structures 308′-1, 308′-2, 308′-5, and 308′-6 may be n-type channel structures.

In addition, the semiconductor structure 300 further includes gate structures 368 longitudinally oriented along the Y direction and wrapping around the channel structures 308′-1, 308′-2, 308′-3, 308′-4, 308′-5, and 308′-6 in accordance with some embodiments. The gate structures 368 may be similar to, or the same as, the gate structures 168, 168-1, 168-2, 168-3, and 168-4 described previously. For example, the gate structures 368 may include n-metal layer, p-metal layers, or a combination thereof.

The semiconductor structure 300 further includes dielectric wall structures 326 longitudinally oriented along the X direction and sandwiched between the channel structures 308′-2 and 308′-3, between the channel structures 308′-4 and 308′-5, and at one side of the channel structures 308′-1 in accordance with some embodiments. The dielectric wall structures 326 may be similar to, or the same as, the dielectric wall structures 126, 126d, 126e, 126f, 126h, 126j, 1261, 126n, and 126o described previously. In some embodiments, the portions of the gate structures 368 at opposite sides of the dielectric wall structures 226 may be different types of metal gate structures.

The semiconductor structure 300 further includes isolation features 388 and 390 longitudinally oriented along the X direction, as shown in FIG. 2O in accordance with some embodiments. The isolation features 388 and 390 are configured to isolate different portions of the gate structures 368. The isolation features 388 may be similar to, or the same as, the isolation features 188, 188a, described previously. Similarly, the isolation feature 390 may be similar to, or the same as, the isolation features 190, 190a, 190b, and 190b described previously.

The semiconductor structure 300 may further include various conductive structures. In some embodiments, the semiconductor structure 300 includes source/drain contacts 401 formed over the source/drain structures (not shown in FIG. 2O, similar to, or the same as, the source/drain structures 150-1, 150-2, 150-3, 150-4, 150-3g, and 150-4g described previously) formed over the channel structures 308′-1, 308′-2, 308′-3, 308′-4, 308′-5, and 308′-6 in accordance with some embodiments. In addition, conductive structures 403 are formed to electrically connect the source/drain contacts 401 and the gate structures 368 in accordance with some embodiments. The semiconductor structure 300 further includes conductive via structures 405 connecting metal layers in an interconnect structure formed over them with elements underneath, in accordance with some embodiments.

In some embodiments, the source/drain contacts 401, the conductive structures 403, and the conductive via structures 405 are made of a conductive material including aluminum (Al), copper (Cu), tungsten (W), titanium (Ti), tantalum (Ta), titanium nitride (TiN), cobalt, tantalum nitride (TaN), nickel silicide (NiS), cobalt silicide (CoSi), copper silicide, tantalum carbide (TaC), tantalum silicide nitride (TaSiN), tantalum carbide nitride (TaCN), titanium aluminide (TiAl), titanium aluminum nitride (TiAlN), other applicable conductive materials, or a combination thereof.

The source/drain contacts 401, the conductive structures 403, and the conductive via structures 405 may further include a liner and/or a barrier layer. For example, a liner (not shown) may be formed on the sidewalls and bottom of the contact trench. The liner may be made of silicon nitride, although any other applicable dielectric may be used as an alternative. The liner may be formed using a plasma enhanced chemical vapor deposition (PECVD) process, although other applicable processes, such as physical vapor deposition or a thermal process, may be used as an alternative. The barrier layer (not shown) may be formed over the liner (if present) and may cover the sidewalls and bottom of the opening. The barrier layer may be formed using a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes. The barrier layer may be made of tantalum nitride, although other materials, such as tantalum, titanium, titanium nitride, or the like, may also be used.

Generally, dielectric wall structures may be formed to isolate various portions of the gate structures and to separate the neighboring source/drain structures. However, during the manufacturing processes of the semiconductor structure, the top portions of the dielectric wall structures may be partially removed, and the function of the dielectric wall structures may be undermined.

Therefore, dielectric wall structures (e.g. the dielectric wall structures 126, 126d, 126e, 126f, 126h, 126j, 1261, 126n, and 126o) with additional cap layers (e.g. the cap layers 124, 124d, 124e, 124h, and 124j) are formed in accordance with some embodiments. The cap layers may help to reduce the amount of the dielectric wall structure being removed during etching processes subsequently performed. More specifically, in the source/drain regions, since the cap layers are only partially, the remaining dielectric wall structures can still be high enough, and therefore the source/drain structures formed at opposite sides of the dielectric wall structures may still be isolated from each other.

Furthermore, in the channel regions, isolation features (e.g. the isolation features 190, 190a, 190b, and 190b) are formed over the dielectric wall structures in accordance with some embodiments. During the formation of isolation trenches (e.g. the trench 186) for forming the isolation features, the cap layers over the dielectric wall structures may also stop the extension of the isolation trenches. According, even if the isolation trenches are not completely aligned with the dielectric wall structures, the risk of damaging the channel structures during the etching processes for forming the isolation trenches can be highly reduced.

In addition, since the dielectric wall structures are formed in relatively narrow spaces between the fin structures, voids may be formed in the dielectric wall structures. However, the cap layers formed at the top portions of the dielectric wall structures may prevent the voids being exposed during the subsequent etching processes, resulting in the risk of circuit short.

In addition, it should be noted that same elements in FIGS. 1A to 2O may be designated by the same numerals and may include materials that are the same or similar and may be formed by processes that are the same or similar; therefore such redundant details are omitted in the interests of brevity. In addition, although FIGS. 1A to 2O are described in relation to the method, it will be appreciated that the structures disclosed in FIGS. 1A to 2O are not limited to the method but may stand alone as structures independent of the method. Similarly, the methods shown in FIGS. 1A to 2O are not limited to the disclosed structures but may stand alone independent of the structures. Furthermore, the channel structures (e.g. the nanostructures) described above may include nanowires, nanosheets, or other applicable nanostructures in accordance with some embodiments.

Also, while the disclosed methods are illustrated and described below as a series of acts or events, it should be appreciated that the illustrated ordering of such acts or events may be altered in some other embodiments. For example, some acts may occur in a different order and/or concurrently with other acts or events apart from those illustrated and/or described above. In addition, not all illustrated acts may be required to implement one or more aspects or embodiments of the description above. Furthermore, one or more of the acts depicted above may be carried out as one or more separate acts and/or phases.

Furthermore, the terms “approximately,” “substantially,” “substantial” and “about” used above account for small variations and may be varied in different technologies and be within the deviation range understood by the skilled in the art. For example, when used in conjunction with an event or circumstance, the terms can refer to instances in which the event or circumstance occurs precisely as well as instances in which the event or circumstance occurs in a close approximation.

Embodiments for forming semiconductor structures may be provided. The semiconductor structure may include channel structures and a dielectric wall structure attached to the channel structures. A gate structure may be formed around the channel structures and an isolation feature may be formed over the dielectric wall structure to separate the gate structure into two portions. In addition, source/drain structures may also attached to opposite sides of the dielectric wall structure, and the dielectric wall structure may prevent the neighboring source/drain structures from merging. Furthermore, the dielectric wall structure may include a bottom portion and a cap layer formed over the bottom portion. The cap layer may help to prevent the dielectric wall structure from being largely removed during the subsequent etching process, and therefore the risk of a short-circuit in the semiconductor structure may be reduced.

In some embodiments, a semiconductor structure is provided. The semiconductor structure includes channel structures vertically stacked over a substrate and a source/drain structure laterally attached to the channel structures in the first direction. The semiconductor structure also includes a dielectric wall structure laterally attached to the channel structures in the second direction. The second direction is different from the first direction. In addition, the dielectric wall structure includes a bottom portion and a cap layer formed over the bottom portion. The semiconductor structure also includes an isolation feature vertically overlapping the cap layer of the dielectric wall structure and a gate structure formed around the channel structures and covering a sidewall of the isolation feature.

In some embodiments, a semiconductor structure is provided. The semiconductor structure includes a dielectric wall structure formed over a substrate. In addition, the dielectric wall structure includes a bottom portion and a cap layer formed over the bottom portion. The semiconductor structure also includes a first isolation feature (that is formed over and in physical contact with the dielectric wall structure) and first channel structures (that are attached to the first sidewall surface of the dielectric wall structure). The semiconductor structure also includes a first gate structure. The first gate structure is abutted against the first channel structures, the dielectric wall structure, and the first isolation feature.

In some embodiments, a method for manufacturing a semiconductor structure is provided. The method for manufacturing the semiconductor structure includes alternately stacking first semiconductor material layers and second semiconductor material layers to form a semiconductor stack over a substrate and patterning the semiconductor stack to form a first fin structure and a second fin structure. In addition, the first fin structure has a first sidewall and a second sidewall opposite the first sidewall, and the second fin structure has a third sidewall facing the second sidewall of the first fin structure and a fourth sidewall opposite the third sidewall. The method for manufacturing the semiconductor structure also includes forming a bottom portion of a dielectric wall structure in a first space between the second sidewall of the first fin structure and the third sidewall of the second fin structure and forming a cap layer of the dielectric wall structure over the core portion in the first space. The method for manufacturing the semiconductor structure also includes removing the first semiconductor material layers of the first fin structure to form first channel structures and removing the first semiconductor material layers of the second fin structure to form second channel structures and forming a first gate structure abutting the first channel structures and a second gate structure abutting the second channel structures. The method for manufacturing the semiconductor structure also includes partially removing the first gate structure and the second gate structure to form a first trench exposing the cap layer of the dielectric wall structure and forming a first isolation feature in the first trench to electrically isolate the first gate structure and the second gate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
channel structures vertically stacked over a substrate;
a source/drain structure laterally attached to the channel structures along a first direction;
a dielectric wall structure laterally attached to the channel structures along a second direction different from the first direction, wherein the dielectric wall structure comprises:
a bottom portion; and
a cap layer formed over the bottom portion;
an isolation feature vertically overlapping the cap layer of the dielectric wall structure; and
a gate structure formed around the channel structures and covering a sidewall of the isolation feature.

2. The semiconductor structure as claimed in claim 1, wherein a void is embedded in the bottom portion.

3. The semiconductor structure as claimed in claim 1, wherein the isolation feature has a first dimension along the second direction, the cap layer has a second dimension along the second direction, and the first dimension is smaller than the second dimension.

4. The semiconductor structure as claimed in claim 1, wherein a bottom surface of the isolation feature is lower than a top surface of the cap layer.

5. The semiconductor structure as claimed in claim 1, wherein the dielectric wall structure comprises:
a dielectric shell layer; and
a core portion over the dielectric shell layer,
wherein the dielectric shell layer is sandwiched between the core portion and the channel structures, and the dielectric shell layer and the core portion are made of different materials.

6. The semiconductor structure as claimed in claim 5, wherein the dielectric shell layer comprises:
a bottom region vertically below the core portion;
a sidewall region laterally around the core portion; and
an extending region laterally around the cap layer.

7. The semiconductor structure as claimed in claim 6, wherein the extending region of the dielectric shell layer has a first thickness along the second direction, the sidewall region of the dielectric shell layer has a second thickness along the second direction, and the first thickness is smaller than the second thickness.

8. The semiconductor structure as claimed in claim 1, wherein the dielectric wall structure comprises:
a liner layer;
a dielectric shell layer formed over the liner layer; and
a core portion formed over the dielectric shell layer,
wherein the liner layer is sandwiched between the dielectric shell layer and the channel structures, and the dielectric shell layer and the liner layer are both in contact with the gate structure.

9. A semiconductor structure, comprising:
a dielectric wall structure formed over a substrate, wherein the dielectric wall structure comprises:
a bottom portion; and
a cap layer formed over the bottom portion;
a first isolation feature formed over and in physical contact with the dielectric wall structure;
first channel structures attached to a first sidewall surface of the dielectric wall structure; and
a first gate structure abutting the first channel structures, the dielectric wall structure, and the first isolation feature.

10. The semiconductor structure as claimed in claim 9, further comprising:
second channel structures attached to a second sidewall surface of the dielectric wall structure opposite the first sidewall surface of the dielectric wall structure; and
a second gate structure abutting the second channel structures, the dielectric wall structure, and the first isolation feature,
wherein the first gate structure is isolated from the second gate structure by the first isolation feature.

11. The semiconductor structure as claimed in claim 10, further comprising:
a first source/drain structure attached to the first sidewall surface of the dielectric wall structure; and
a second source/drain structure attached to the second sidewall surface of the dielectric wall structure,
wherein a first top surface of a first portion of the dielectric wall structure sandwiched between the first source/drain structure and the second source/drain structure is lower than a second top surface of a second portion of the dielectric wall structure sandwiched between the first channel structures and the second channel structures.

12. The semiconductor structure as claimed in claim 10, further comprising:
a base fin structure protruding from the substrate, wherein the dielectric wall structure is in direct contact with the base fin structure.

13. The semiconductor structure as claimed in claim 12, wherein the base fin structure vertically overlaps the first channel structures and the second channel structure.

14. The semiconductor structure as claimed in claim 12, wherein a bottom surface of the dielectric wall structure is lower than a top surface of the base fin structure.

15. The semiconductor structure as claimed in claim 9, further comprising:
a second isolation feature laterally spaced apart from the first isolation feature,
wherein the first isolation feature and the second isolation feature physically contact opposite sides of the first gate structure, and the second isolation feature is thicker than the first isolation feature.

16. A method for manufacturing a semiconductor structure, comprising:
alternately stacking first semiconductor material layers and second semiconductor material layers to form a semiconductor stack over a substrate;
patterning the semiconductor stack to form a first fin structure and a second fin structure, wherein the first fin structure has a first sidewall and a second sidewall opposite the first sidewall, and the second fin structure has a third sidewall facing the second sidewall of the first fin structure and a fourth sidewall opposite the third sidewall;
forming a bottom portion of a dielectric wall structure in a first space between the second sidewall of the first fin structure and the third sidewall of the second fin structure;
forming a cap layer of the dielectric wall structure over the bottom portion in the first space;
removing the first semiconductor material layers of the first fin structure to form first channel structures and removing the first semiconductor material layers of the second fin structure to form second channel structures;
forming a first gate structure abutting the first channel structures and a second gate structure abutting the second channel structures;
partially removing the first gate structure and the second gate structure to form a first trench exposing the cap layer of the dielectric wall structure; and
forming a first isolation feature in the first trench to electrically isolate the first gate structure and the second gate structure.

17. The method for manufacturing the semiconductor structure as claimed in claim 16, further comprising:
forming a dielectric shell layer covering the first sidewall and the second sidewall of the first fin structure and the third sidewall and the fourth sidewall of the second fin structure;
forming a core portion over the dielectric shell layer, wherein the first space is substantially filled by the dielectric shell layer and the core portion;
partially removing the dielectric shell layer and the core portion to expose the first sidewall of the first fin structure and the fourth sidewall of the second fin structure;
recessing the dielectric shell layer and the core portion to form a recess in an upper region of the first space; and
forming the cap layer in the recess.

18. The method for manufacturing the semiconductor structure as claimed in claim 16, further comprising:
forming a second trench through the first gate structure; and
forming a second isolation feature in the second trench,
wherein a top surface of the first isolation feature is substantially level with a top surface of the second isolation feature, and a bottom surface of the first isolation feature is higher than a bottom surface of the second isolation feature.

19. The method for manufacturing the semiconductor structure as claimed in claim 16, further comprising:
partially removing the cap layer when forming the first trench, so that the first trench extends into the dielectric wall structure.

20. The method for manufacturing the semiconductor structure as claimed in claim 16, further comprising:
forming a spacer layer covering the first sidewall of the first fin structure and the fourth sidewall of the second fin structure;
performing an etching process to form a first source/drain recess in the first fin structure, a second source/drain recess in the second fin structure, a first fin spacer with the spacer layer at a first side of the first source/drain recess, and a second fin spacer with the spacer layer at a second side of the second source/drain recess; and
forming a first source/drain structure in the first source/drain recess and a second source/drain structure in the second source/drain recess,
wherein the cap layer is also partially etched during the etching process.
